(19) United States
(12) Patent Application Publication
(10) Pub. No.: US 2017/0077180 A1
(43) Pub. Date: Mar. 16, 2017

(54) NONVOLATILE SEMICONDUCTOR MEMORY DEVICE

(71) Applicant: KABUSHIKI KAISHA TOSHIBA, Minato-ku (JP)

(72) Inventors: Sanae ITO, Yokohama (JP); Takashi IZUMIDA, Yokohama (JP); Hikari TAJIMA, Mitaka (JP)

(73) Assignee: KABUSHIKI KAISHA TOSHIBA, Minato-ku (JP)

(21) Appl. No.: 14/995,609

(22) Filed: Jan. 14, 2016

Related U.S. Application Data
(60) Provisional application No. 62/216,572, filed on Sep. 10, 2015.

(51) Int. Cl. H01L 27/24; H01L 45/00

(52) U.S. Cl. CPC H01L 27/2454; H01L 27/2481; H01L 45/085; H01L 45/1233; H01L 45/1253; H01L 45/146

(57) ABSTRACT

A nonvolatile semiconductor memory device includes a memory cell array. The memory cell array includes conducting layers, semiconductor layers, variable resistance films, and first wirings. The conducting layers are laminated in a first direction perpendicular to a substrate, and extend in a second direction parallel to the substrate. The semiconductor layers extend in the first direction. The variable resistance films are disposed at intersection points of the conducting layers and the semiconductor layers. Each first wiring is opposed to the semiconductor layer via a gate insulating film. The first wirings extend in the first direction. Each variable resistance film has a first thickness at a first part. The first thickness is in a direction from the conducting layers to the semiconductor layer. The variable resistance film has a second thickness at a second part. The second part is far from the substrate more than the first part. The second thickness is smaller than the first thickness.

### CROSS-REFERENCE TO RELATED APPLICATIONS

This application is based upon and claims the benefit of priority from the prior U.S. Provisional Application 62/216,572, filed on Sep. 10, 2015, the entire contents of which are incorporated herein by reference.

### FIELD

Embodiments described herein generally relate to a nonvolatile semiconductor memory device.

### BACKGROUND

Recently, in association with highly integrated semiconductor memory devices, LSI devices constituting these semiconductor memory devices have been increasingly miniaturized. For miniaturization of these LSI devices, not only simply thinning the line width, but also improvements in dimensional accuracy and position accuracy of a circuit pattern are desired. As a technique to overcome such problem, there has been proposed a Resistive RAM (ReRAM) that uses variable resistive elements, which reversibly change a resistance value, as a memory. This ReRAM includes the variable resistive element between a sidewall of a word line extending parallel to a substrate and a sidewall of a bit line extending perpendicular to the substrate. This three-dimensional structure ensures further highly integrated memory cell array. With this three-dimensional-structured ReRAM, On/Off of each bit line is required to be accurately controlled.

### BRIEF DESCRIPTION OF THE DRAWINGS

FIG. 1 is an exemplary block diagram of a semiconductor memory device according to first to fifth embodiments;

FIG. 2 is an exemplary circuit diagram of a memory cell array 11 according to the first to the fifth embodiments;

FIG. 3 is an exemplary perspective view illustrating a laminated structure of the memory cell array 11 according to the first to the fifth embodiments;

FIG. 4A and FIG. 4B are top view and cross-sectional view illustrating the configuration of the memory cell array 11 according to the first to the fifth embodiments;

FIG. 5 is a schematic cross-sectional view illustrating a part including a plurality of memory cells MC in the memory cell array 11 according to the first embodiment;

FIG. 6 is a perspective view describing an example of an access to one memory cell MC in the memory cell array 11 according to the first to the fifth embodiments;

FIG. 7 is a conceptual cross-sectional view describing a way of flow of a current when accessing the plurality of memory cells MC in the memory cell array 11 according to the first embodiment;

FIG. 8 to FIG. 17 are exemplary schematic cross-sectional views illustrating a method for manufacturing the memory cell array 11 according to the first embodiment;

FIG. 18 is an exemplary schematic cross-sectional view illustrating the configuration of the memory cell array 11 according to Comparative Example and the way of the flow of the current in this Comparative Example;

FIG. 19 is a perspective view illustrating a part including the plurality of memory cells MC in the memory cell array 11 according to the second embodiment, and FIG. 20 is a schematic cross-sectional view illustrating a part including the plurality of memory cells MC in the memory cell array 11 according to the second embodiment;

FIG. 21 to FIG. 31 are exemplary schematic cross-sectional views illustrating a method for manufacturing the memory cell array 11 according to the second embodiment;

FIG. 32 is a schematic cross-sectional view illustrating a part including the plurality of memory cells MC in the memory cell array 11 according to the third embodiment;

FIG. 33 is a schematic cross-sectional view illustrating a part including the plurality of memory cells MC in the memory cell array 11 according to the fourth embodiment; and

FIG. 34 is a schematic cross-sectional view illustrating a part including the plurality of memory cells MC in the memory cell array 11 according to the fifth embodiment.

### DETAILED DESCRIPTION

A nonvolatile semiconductor memory device includes a memory cell array. The memory cell array includes conducting layers, semiconductor layers, variable resistance films, and first wirings. The conducting layers are laminated in a first direction perpendicular to a substrate, and extend in a second direction parallel to the substrate. The semiconductor layers extend in the first direction. The variable resistance films are disposed at intersection points of the conducting layers and the semiconductor layers. Each first wiring is opposed to the semiconductor layer via a gate insulating film. The first wirings extend in the first direction. Each variable resistance film has a first thickness at a first part. The first thickness is in a direction from the conducting layers to the semiconductor layer. The variable resistance film has a second thickness at a second part. The second part is far from the substrate more than the first part. The second thickness is smaller than the first thickness.

### First Embodiment

First, the following describes a nonvolatile semiconductor memory device according to the first embodiment.

### Configuration

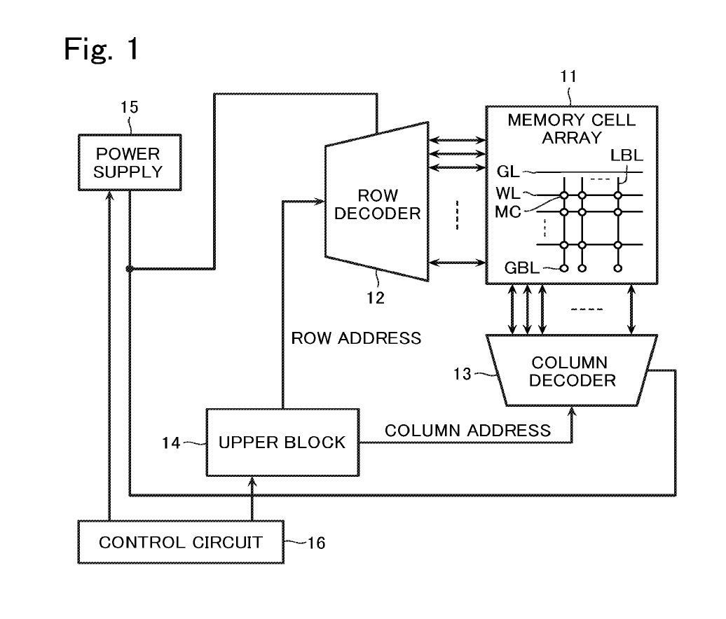

The following describes an overall configuration of a nonvolatile semiconductor memory device according to the first embodiment with reference to FIG. 1. FIG. 1 is an exemplary block diagram of the nonvolatile semiconductor memory device according to the first embodiment. As illustrated in FIG. 1, the nonvolatile semiconductor memory device includes the memory cell array 11, a row decoder 12, a column decoder 13, an upper block 14, a power supply 15, and a control circuit 16.

The memory cell array 11 includes a plurality of word lines WL and local bit lines LBL, which intersect with one another, and memory cells MC, which are disposed in the respective intersection portions of these lines. Application of a voltage from a gate line GL via a gate electrode GE selects the local bit line LBL. The lower end of the local bit line LBL is electrically connected to a global bit line GBL. The row decoder 12 selects the word line WL and the local bit line LBL for access (data erasure/writing/reading). The column decoder 13 includes a driver that selects the global bit line GBL for access to control an access operation.

The upper block 14 selects the memory cell MC in the memory cell array 11 to be accessed. The upper block 14 gives a row address and a column address to the row decoder 12 and the column decoder 13, respectively. The power supply 15 generates combinations of predetermined voltages corresponding to the respective operations of data erasure/writing/reading and supplies the combinations to the row decoder 12 and the column decoder 13. The control circuit 16 performs a control such as transmission of an address to the upper block 14 in response to an external command and controls the power supply 15.

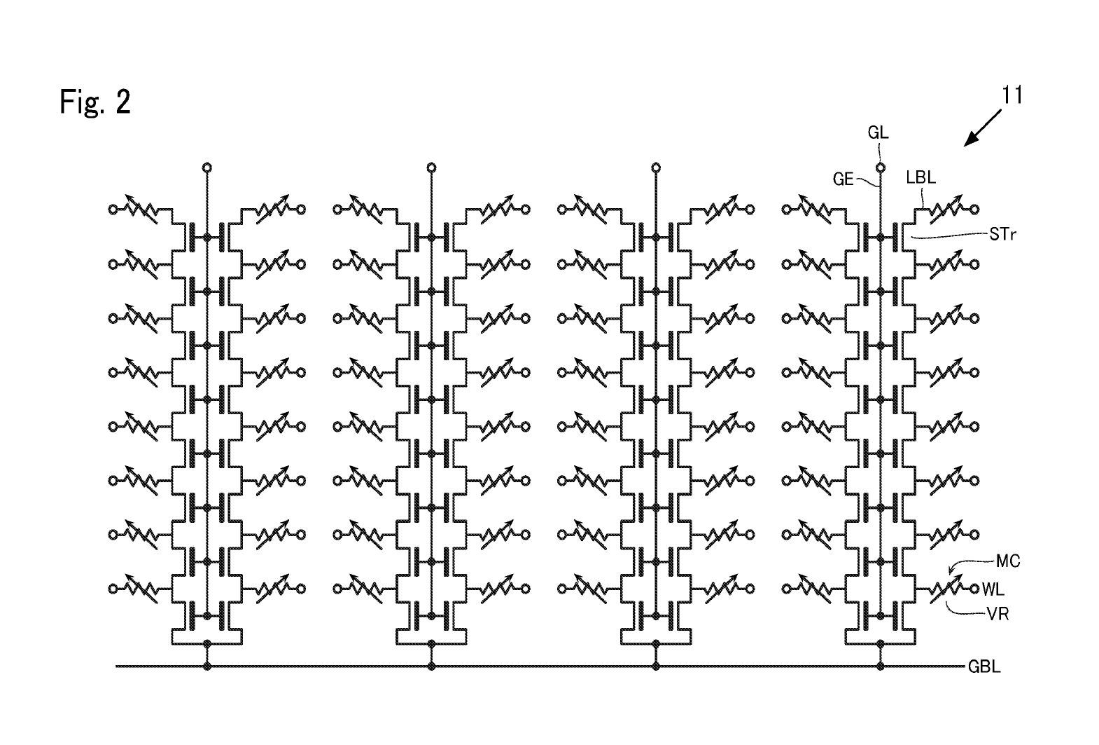

Next, the following describes a circuit configuration of the memory cell array 11 in the embodiment using FIG. 2, which illustrates an exemplary equivalent circuit diagram of the memory cell array 11.

As illustrated in FIG. 2, the plurality of memory cells MC are disposed in the memory cell array 11 of the embodiment. The memory cells MC are disposed at intersection portions of the word lines WL and the local bit lines LBL. The local bit line LBL is connected to the global bit line GBL, which is illustrated at the lower portion of FIG. 2.

The nonvolatile semiconductor memory device of the embodiment includes a plurality of the configurations illustrated in FIG. 2 both in the horizontal direction on the paper and the vertical direction on the paper.

The memory cell MC includes a variable resistive element VR. The variable resistive element VR is electrically rewritable and stores data in a non-volatile manner based on the resistance value. The variable resistive element VR changes from a high resistance state (a reset state) to a low resistance state (a setting state) by a setting operation. The setting operation applies a voltage at a certain magnitude or more to both ends of the variable resistive element VR. The variable resistive element VR changes from the low resistance state (the setting state) to the high resistance state (the reset state) by a reset operation. The reset operation applies a voltage at a certain magnitude or more to both ends of the variable resistive element VR. Immediately after the manufacture, the variable resistive element VR is in a state of not easily changing its resistive state and in the high resistance state. Therefore, a forming operation, which applies a high voltage equal to or more than the setting operation and the reset operation to both ends of the variable resistive element VR, is performed. This forming operation forms a region (a filament path) where a current is likely to locally flow in the variable resistive element VR. This allows the variable resistive element VR to easily change the resistive state, being operable as a storage element.

To access the one selected memory cell MC, the column decoder 13 selects the local bit line LBL connected to the memory cell MC. That is, a predetermined voltage is applied to the gate line GL corresponding to the selected local bit line LBL. Simultaneously, a voltage of a value different from the voltage applied to the gate line GL is applied to the global bit line GBL corresponding to the selected memory cell MC. Then, a potential difference between the gate electrode GE, which is electrically connected to the gate line GL, and the global bit line GBL generates an inversion layer on the local bit line LBL. This forms a channel (a current path) in the local bit line LBL. That is, with the nonvolatile semiconductor memory device of the embodiment, the gate electrode GE, the local bit line LBL, and a gate insulating film (described later, not illustrated in FIG. 2) constitute a selection transistor STr. The gate insulating film is interposed between the gate electrode GE and the local bit line LBL. The selection transistor STr employs the gate electrode GE as a gate and the local bit line LBL as a channel. The plurality of selection transistors STr are connected to the one local bit line LBL in series. A predetermined selected voltage V_{A} is applied to the word line WL connected to the selected memory cell MC. Then, the potential difference between these word line WL and global bit line GBL causes a current to flow, allowing access to the memory cell MC. A non-selected voltage V_{B}, which is smaller than V_{A}, is applied to the word line WL connected to the non-selected memory cell MC. This causes the current not to flow in the non-selected memory cell MC.

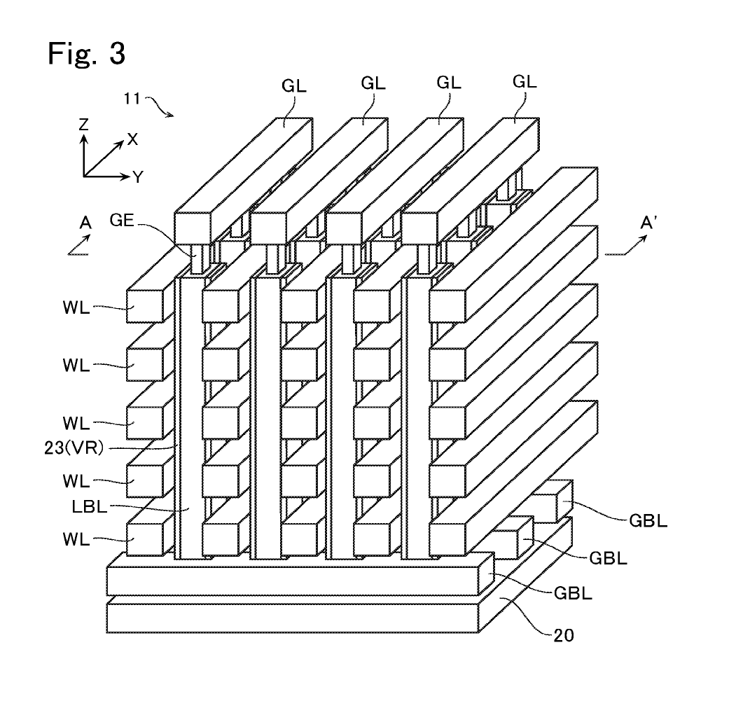

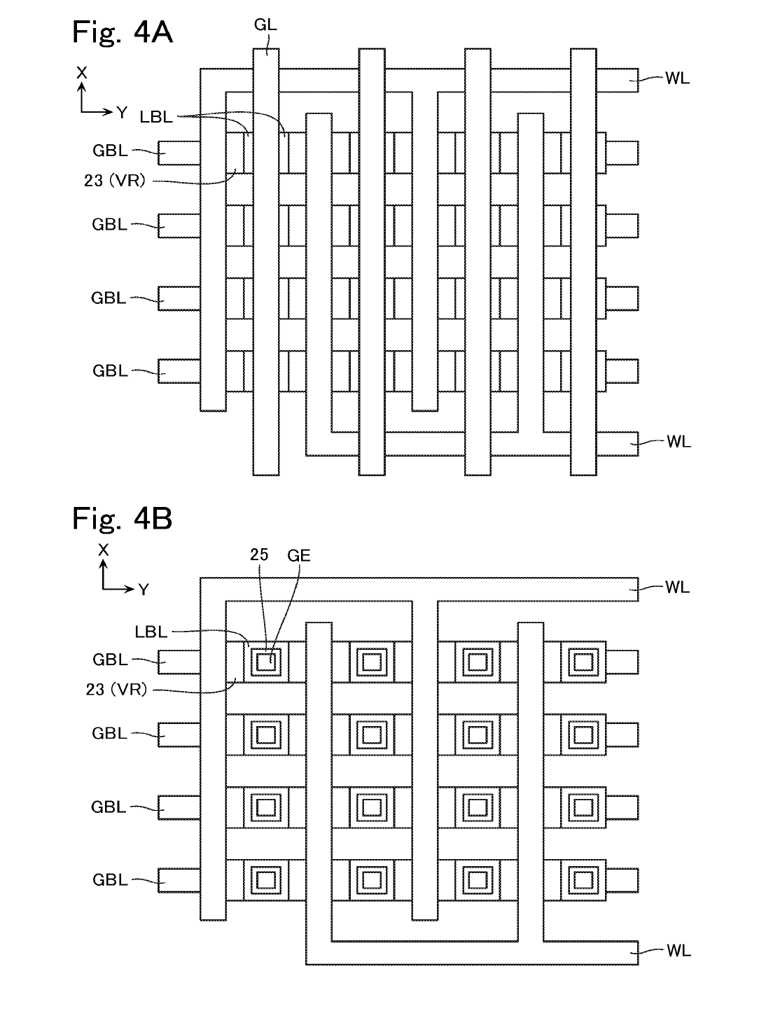

Next, the following describes the schematic configuration of the memory cell array 11 according to the first embodiment with reference to FIG. 3, FIG. 4A, and FIG. 4B. FIG. 3 is a perspective view illustrating an exemplary laminated structure of the memory cell array 11. FIG. 4A is a schematic top view of the memory cell array 11 whose top surface is viewed from a Z direction. FIG. 4B is a cross-sectional view taken along the line A-A′ of FIG. 3.

FIG. 3, FIG. 4A, and FIG. 4B illustrate only layers required for a memory function and an access function but do not illustrate an interlayer insulating layer 22, which insulates between the layers.

As illustrated in FIG. 3, the word lines WL (the conducting layers) are parallel to a surface of a substrate 20. The plurality of word lines WL have a length in the X direction and are disposed in the Y direction, which is perpendicular to the X direction. As illustrated in FIG. 4A and FIG. 4B, these word lines WL have two sets of comb shape viewed from the Z direction. The teeth of the combs are relatively nested to one another.

The local bit lines LBL extend in a columnar manner in the vertical direction (the Z-axis direction) with respect to the substrate 20. The local bit lines LBL are disposed in an array shape in the X direction and the Y direction (The example in FIG. 3 illustrates these local bit lines LBL of 3×4=12 pieces). The local bit lines LBL are electrically connected to the global bit lines GBL on the substrate 20 side.

In FIG. 3, the memory cell array 11 is consisted of three components; the word lines WL, the local bit lines LBL, and variable resistance films 23 disposed between both. The local bit lines LBL extend in the Z direction, which are perpendicular to the substrate 20. The word lines WL extend in the X direction. Both side surfaces of the one local bit line LBL in the Y direction, the word lines WL contact via the variable resistance films 23. The variable resistance films 23 at the intersection portions of these local bit lines LBL and word lines WL constitute the variable resistive elements VR. A large number of the word lines WL are laminated on the substrate 20. Accordingly, the memory cell array 11 is formed by lamination at predetermined pitches in the Z direction perpendicular to the substrate 20.

As illustrated in FIG. 3, global bit lines GBL are disposed on the substrate 20. The global bit lines GBL extend in the Y direction and are arrayed at predetermined pitches in the X direction.

The word line WL is made of transition metal alone or the nitride of the transition metal as the conductive material. As an example, the word line WL can be made of titanium (Ti), titanium nitride (TiN), tungsten (W), tungsten nitride (WN), tungsten silicide (WSix), tantalum (Ta), tantalum nitride (TaN), tantalum silicide (TaSix), palladium silicide (PdSix), erbium silicide (ErSix), yttrium silicide (YSix), platinum silicide (PtSix), hafnium silicide (HfSix), nickel silicide (NiSix), cobalt silicide (CoSix), titanium silicide (TiSix), vanadium silicide (VSix), chromium silicide (CrSix), manganese silicide (MnSix), iron silicide (FeSix), ruthenium (Ru), molybdenum (Mo), vanadium (V), chrome (Cr), manganese (Mn), iron (Fe), cobalt (Co), nickel (Ni), gold (Au), silver (Ag), or copper (Cu); or the compound of these elements. However, the word line WL may be made of polysilicon to which impurities are doped.

On the side surfaces of the word lines WL in the Y direction, the variable resistance films 23, which extend in the Z direction, are disposed. The variable resistance film 23 is, for example, made of a metal oxide film such as hafnium oxide (HfOX). The thickness of the variable resistance film 23 is, for example, around 5 nm. However, the thickness can be appropriately changed in the range of around 2 to 10 nm. As materials other than HfO_{X}, a transition metal oxide, such as chrome (Cr), tungsten (W), vanadium (V), niobium (Nb), tantalum (Ta), titanium (Ti), zirconium (Zr), scandium (Sc), yttrium (Y), thorium (Tr), manganese (Mn), iron (Fe), ruthenium (Ru), osmium (Os), cobalt (Co), nickel (Ni), copper (Cu), zinc (Zn), cadmium (Cd), aluminum (Al), gallium (Ga), indium (In), tin (Sn), lead (Pb), and bismuth (Bi), or an oxide such as a so-called rare-earth element from lanthanum (La) to lutetium (Lu) can be used. The variable resistance film 23 is disposed in common across the plurality of word lines WL in FIG. 3. However, the variable resistance films 23 may be constituted so as to be separately disposed for each of the word lines WL.

As illustrated in FIG. 3, FIG. 4A, and FIG. 4B, the columnar-shaped local bit lines LBL, which are made of semiconductor and extend in the Z direction, are disposed on the side surfaces of the variable resistance films 23 on the opposite side from the word lines WL. That is, the local bit lines LBL are in contact with the word lines WL via the variable resistance films 23. The local bit lines LBL are disposed in a matrix in the X direction and the Y direction. The local bit line LBL is formed of a semiconductor, such as non-doped polysilicon.

The semiconductor, which constitutes the local bit line LBL, may be made of polysilicon to which impurities such as phosphorus (P), boron (B), or arsenic (As) is added, as well as polysilicon to which impurities are not doped.

With the nonvolatile semiconductor memory device of the embodiment having the above-described configuration, the memory cells MC including the variable resistive elements VR are disposed at the portions where the word lines WL intersect with the local bit lines LBL. Therefore, the memory cells MC have a three-dimensional matrix structure disposed along the respective X, Y, and Z directions. In the embodiment, as illustrated in FIG. 4A and FIG. 4B, the planar shape of the local bit line LBL is a rectangular shape. Regarding the relationship between lengths of this rectangular shape in the X direction and the Y direction, either one of the length may be longer than the other or both may have the identical length. The planar shape of the local bit line LBL is not limited to the rectangular shape but may be a circular shape or an elliptical shape.

As illustrated in FIG. 3, the plurality of local bit lines LBL are connected in common to the one global bit line GBL at the lower ends in the Z direction. The global bit lines GBL extend in the Y direction and are disposed on the substrate 20 at predetermined pitches in the X direction. The global bit line GBL is, for example, made of metal such as tungsten (W).

As illustrated in FIG. 3 and FIG. 4A, the gate lines GL are disposed upward more than the word line WL on the uppermost layer. The gate lines GL extend in the X direction and are arrayed at predetermined pitches in the Y direction. As illustrated in FIG. 3, to the one gate line GL, the plurality of gate electrodes GE aligned in the X direction are connected in common. As the material that can be used for the gate line GL, the material identical to the word line WL can be used.

As illustrated in FIG. 3 and FIG. 4B, the gate electrode GE is disposed inside the columnar-shaped local bit line LBL via the gate insulating film 25. The gate electrodes GE extend in the Z direction. That is, the side surfaces of the local bit line LBL are opposed to the side surfaces of the gate electrode GE via a gate insulating film 25.

The gate electrode GE, for example, can be made of n⁺ type polysilicon with high doped concentration and titanium nitride (TiN). The gate insulating film 25 may be SiO₂, alumina, or a similar material.

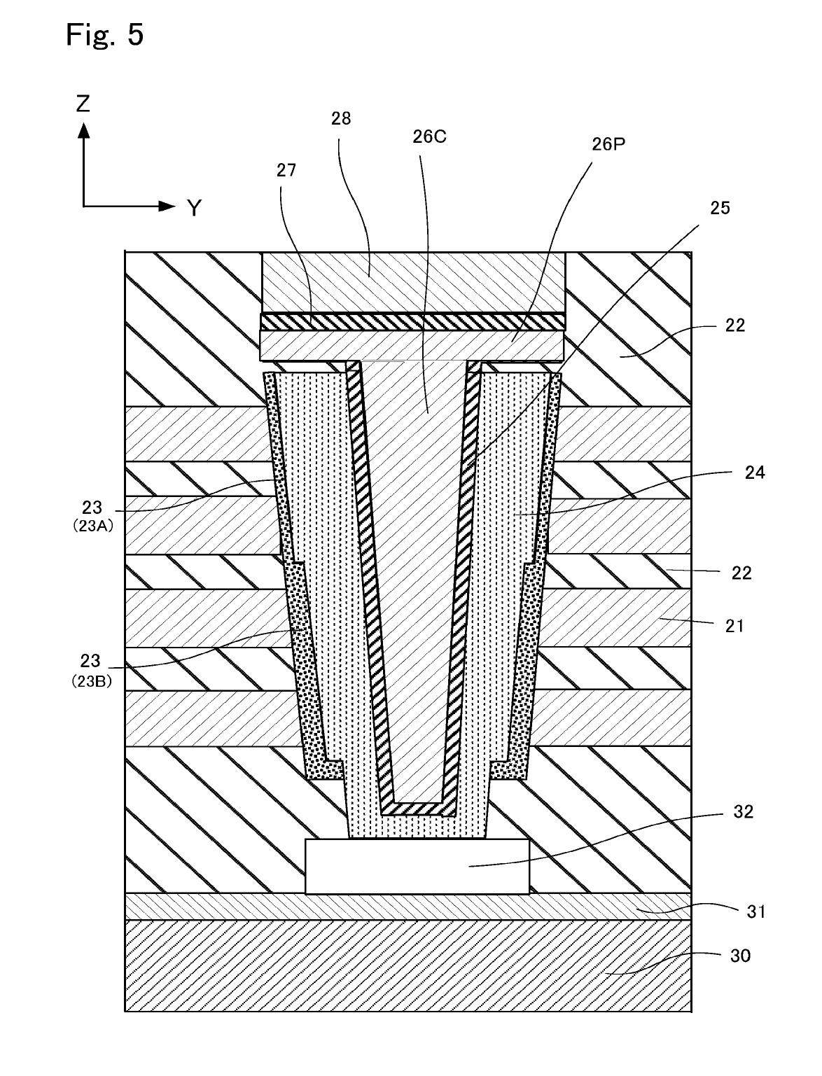

FIG. 5 is a schematic cross-sectional view illustrating a part including the plurality of memory cells MC in the memory cell array 11. In FIG. 3, the number of the word lines WL is 5; however, FIG. 5 illustrates the four word lines WL.

As illustrated in FIG. 5, this embodiment laminates the interlayer insulating layers 22 and conducting layers 21 in alternation in the Z direction on the substrate 20 (not illustrated). The conducting layer 21 functions as the word line WL. The variable resistance film 23 (23A and 23B) is disposed in common on the end side surfaces of these conducting layers 21 in the Y direction. This variable resistance film 23 functions as the variable resistive element VR. This variable resistance film 23 has a thick film on the side close to the substrate 20, and has a thin film on the side far from the substrate 20. In FIG. 5, the variable resistance film with thick film is configured as a first part 23B, and the variable resistance film with thin film is configured as a second part 23A. As described later, providing this difference in film thickness allows restraining a variation in current during access. The variable resistance film 23 includes a semiconductor layer 24 (the local bit line LBL: a semiconductor layer) on the side surface opposite to the conducting layers 21 (the word lines WL). The semiconductor layer 24 has the columnar shape and extends in the Z direction.

As illustrated in FIG. 5, the semiconductor layer 24 has a tapered shape whose thickness or width decreases at the bottom portion. The cause that the thickness of this local bit line LBL thins on the bottom portion side is described later in detail in the steps for the process. This is caused in the process of digging a vertical, deep hole penetrating the large number of laminated conducting layers 21 (word lines WL) and interlayer insulating layers 22 up to near the global bit line GBL. As the hole deepens, the vertical process becomes difficult.

A core-like conducting layer 26C (a first wiring) is disposed inside the columnar-shaped semiconductor layer 24 via the gate insulating film 25. In other words, the semiconductor layer 24 has a hollow columnar shape that surrounds the peripheral area of the conducting layer 26C via the gate insulating film 25. The conducting layer 26C corresponds to the gate electrode GE in FIG. 4B. The core-like conducting layer 26C does not penetrate up to the lower end of the semiconductor layer 24. Consequently, the semiconductor layer 24 is formed into an approximately U shape viewed from the Y-Z cross section. The conducting layer 26C, for example, can be made of highly doped n⁺ type polysilicon, such as phosphorus (P) as a dopant, or highly doped titanium nitride (TiN).

Additionally, the conducting layer 26C forms a plate-shaped conducting layer 26P upward more than the word line WL on the uppermost layer. Although the conducting layer 26C and the plate-shaped conducting layer 26P are made of the identical material, for convenience of explanation, reference numerals are given to the respective conducting layer 26C and plate-shaped conducting layer 26P. This conducting layer 26P is electrically connected to a conducting layer 28 (the gate line GL: a second wiring) via a barrier layer 27 made of titanium silicide (TiSix) or a similar material. The barrier layer 27 is not an electrical barrier but is to prevent diffusion of impurities. The conducting layer 28 (the gate line GL) has a function to provide a gate bias to the conducting layer 26C.

The lower end of the semiconductor layer 24 is electrically connected to a conducting layer 30 (the global bit line GBL: a third wiring) via a conducting layer 32, which is made of n⁺ type polysilicon or a similar material, and a barrier layer 31, which is made of titanium nitride or a similar material. The barrier layer 31 functions as a barrier metal to prevent a diffusion of impurities or a similar material to the conducting layer 30. The conducting layer 32 causes the conducting layer 30 to be in ohmic contact with the semiconductor layer 24. The conducting layer 30 is disposed on the substrate 20 via an insulating film 29 made of silicon oxide or a similar material.

In the case where the conducting layer 26C (the gate electrode GE) provides an electric field to the semiconductor layer 24 (the local bit line LBL), the semiconductor layer 24 forms a channel (a current path) near the interface with the gate insulating film 25. This switches the selection transistor STr, which is illustrated in FIG. 2, to a conductive state.

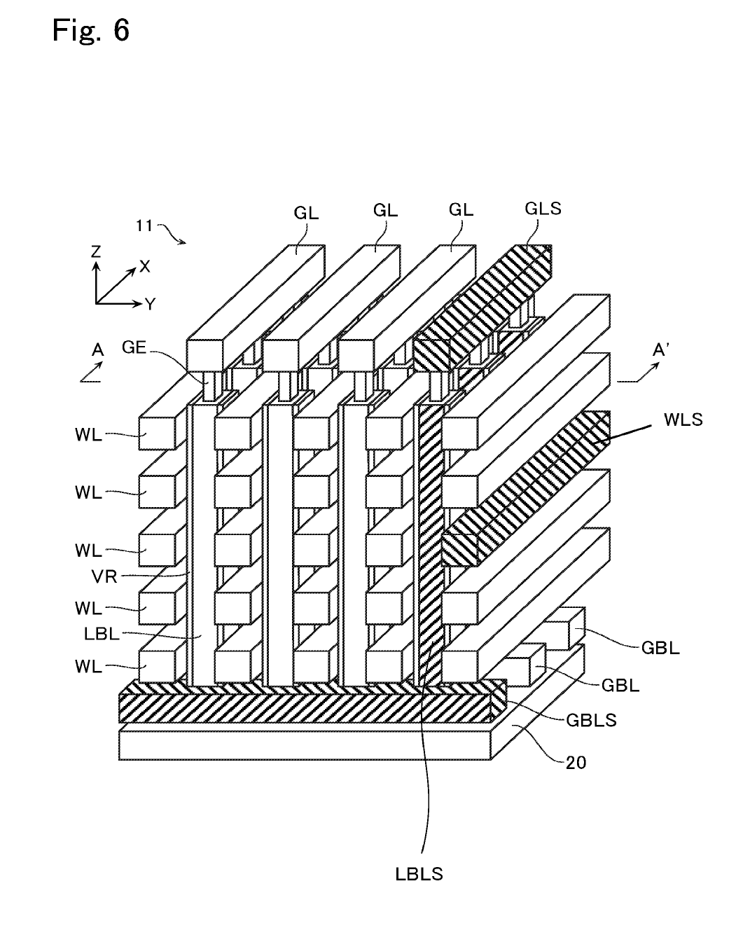

FIG. 6 is a perspective view for describing an access operation of the memory cell array 11. Except for the hatching provided for explanation, the drawing illustrates the structure of the memory cell array 11 similar to FIG. 3. In FIG. 6, it is assumed that a hatched gate line GLS is selected among the four gate lines GL aligned on the uppermost layer and a voltage is applied to the gate line GLS. The voltage applied to the selected gate line GLS is applied to the gate electrodes GE embedded into the local bit lines LBL. This application of the gate voltage forms channels in the local bit lines LBL. This turns all the selection transistors STr connected in series to the ON state, generating a conductive state. FIG. 6 hatches the local bit lines LBL thus the channels are formed and denotes the local bit lines LBL as LBLS. As apparent from the drawing, this gate voltage is applied not only the hatched local bit line LBL on the frontmost, but also is applied to the all local bit lines LBL under the selected gate line GLS. Accordingly, the channels are formed in all the local bit lines LBL in this row, allowing the all local bit lines LBL where the channels are formed to be in the conductive state.

Here, to access the specific memory cell MC, assume that the row decoder 12 and the column decoder 13 select the following word line WL and global bit line GBL. A hatched word line WLS, which is the third top word line in FIG. 6, is selected to apply the voltage. Next, the voltage is applied to a hatched global bit line GBLS, which is the frontmost global bit line GBL among the three global bit lines GBL. In view of this, among the all memory cells MC, the voltage is applied only to the one variable resistive element VR, this allows a memory operation, such as a setting operation/reset operation/reading operation.

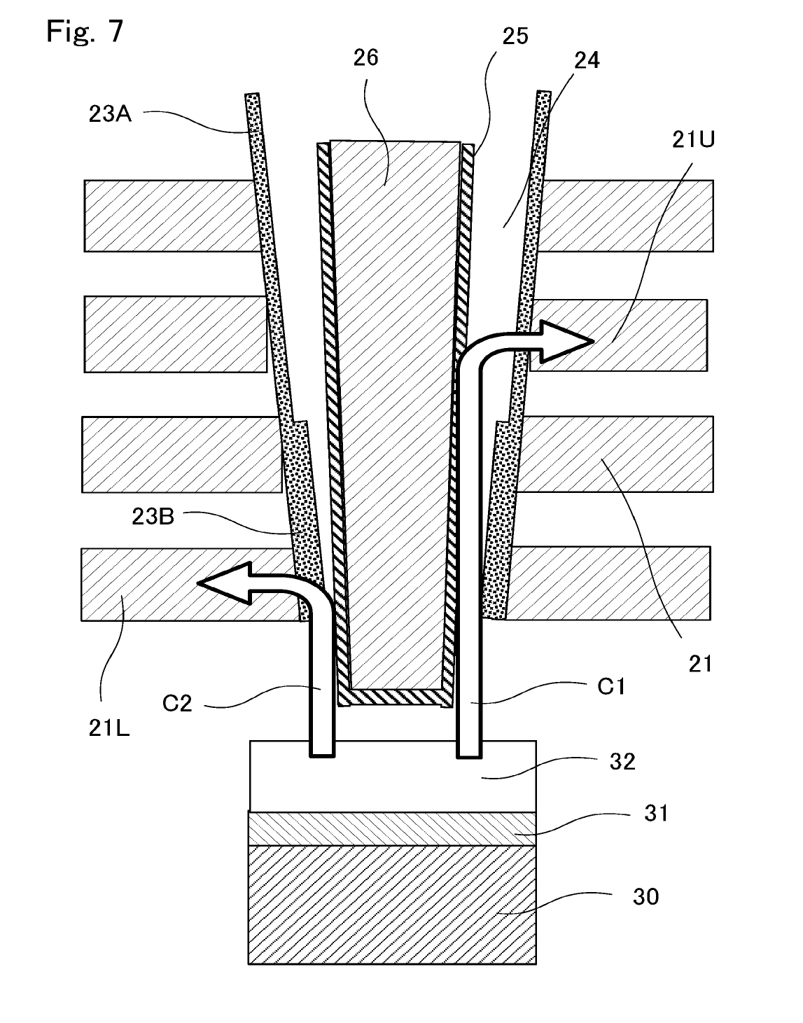

FIG. 7 is a drawing for describing a memory operation in the first embodiment. FIG. 7 is a conceptual cross-sectional view illustrating a part including the plurality of memory cells MC in the memory cell array 11. For simplification of the drawing, the illustration of the interlayer insulating layers 22, the conducting layer 26P, the barrier layer 27, and the conducting layer 28, which are illustrated in FIG. 5, are omitted.

As described above, by applying the electric field to a conducting layer 26 (the gate line GL), the channel is formed on the interface of the semiconductor layer 24 (the local bit line LBL) on the gate insulating film 25 side. This allows applying a voltage to the variable resistance film 23 (the variable resistive element VR), which is disposed between the selected conducting layer 30 (the global bit line GBL) and a selected word line 21U or a word line 21L. This application of the voltage causes a current to flow through the selected word line 21 from the conducting layer 30 via the variable resistance film 23. FIG. 7 expresses this current by an arrow C1 and an arrow C2.

FIG. 7 describes two cases. The first case is that the conducting layer 21U (the word line WL on the upper layer far from the global bit line GBL), which is the third word line WL from the bottom, is selected. The other one case is that the conducting layer 21L (the word line WL on the lowermost layer close to the global bit line GBL), which is the lowermost word line WL, is selected.

In the first embodiment, the variable resistance film 23 has a first thickness (the variable resistance film 23B) at the first part on the substrate side. The variable resistance film 23 has a second thickness (the variable resistance film 23A) smaller than the first thickness at the second part, which is far from the substrate more than this first part. Here, the “thickness” means a thickness in the direction from the conducting layer 21 to the semiconductor layer 24. Here, the boundary of the first part and the second part is freely configured. Additionally, here, the “thickness” may be defined as the average value of the film thicknesses of the variable resistance film 23 at these first part or second part. Instead of the average value, the “thickness” may be defined as the maximum value and the minimum value. The variable resistance film 23A may vary in the first part. The same applies to the second part.

This difference in thickness of this variable resistance film 23 generates a difference in the resistance value of the variable resistive element VR. This allows cancelling the increase in the resistance value caused by the tapered shape of the local bit line LBL.

In FIG. 7, the arrow C1 expresses the current that passes through from the conducting layer 30 (the global bit line GBL) to the semiconductor layer 24 (the local bit line LBL) and then reaches the third conducting layer 21U from the bottom. Due to the thin thickness of the variable resistance film 23, the resistance value of the variable resistance film 23 (23A) in this current path is a low resistance. Although the channel length of the local bit line LBL is long, a sufficient current value is obtained from the current flowing through this path.

The following describes the other one current path. The arrow C2 expresses the current flowing through the conducting layer 21L on the most substrate side. Due to the thick film thickness, the resistance value of the semiconductor layer 24 (the local bit line LBL) (23B) in this current path is high. Meanwhile, since the channel length of the semiconductor layer 24 (the local bit line LBL) is short, the resistance value of the channel is low. However, the resistance of the semiconductor layer 24 (the local bit line LBL) is large. Therefore, the current flowing through this current path becomes a current value equivalent to the former example. The thicknesses of the two arrows are identical for notation. This expresses that the magnitude of the current value is equivalent.

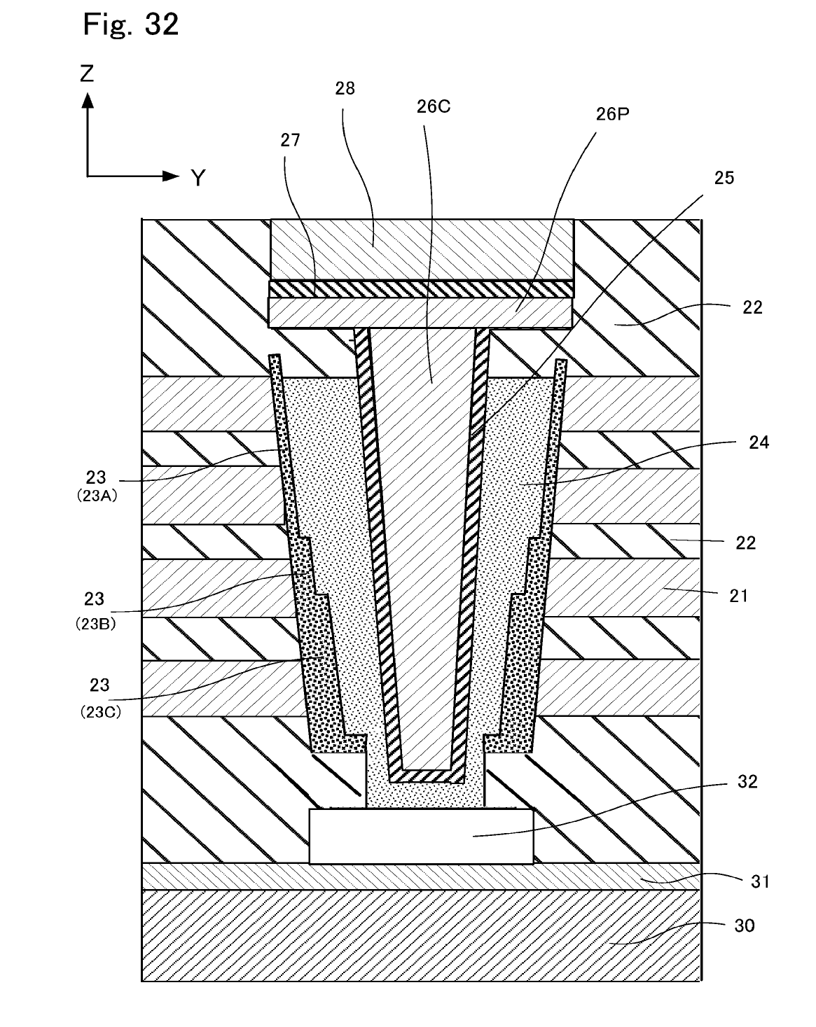

The first embodiment describes the thickness of the variable resistance film 23 to the shape having one-step level difference. However, it is apparent that the similar effect can be expected in the case where the variable resistance film 23 has the film thicknesses of multiple levels and the case where the film thickness consecutively changes. Here, “consecutively” also includes the change in discontinuous film thickness at some points in addition to the consecutive change in the film thickness of the variable resistance film 23 in the laminating direction. FIG. 32 is a schematic cross-sectional view illustrating a part including the plurality of memory cells MC in the memory cell array 11 according to the third embodiment. In this embodiment, the thickness of the variable resistance film 23 differs in multiple levels.

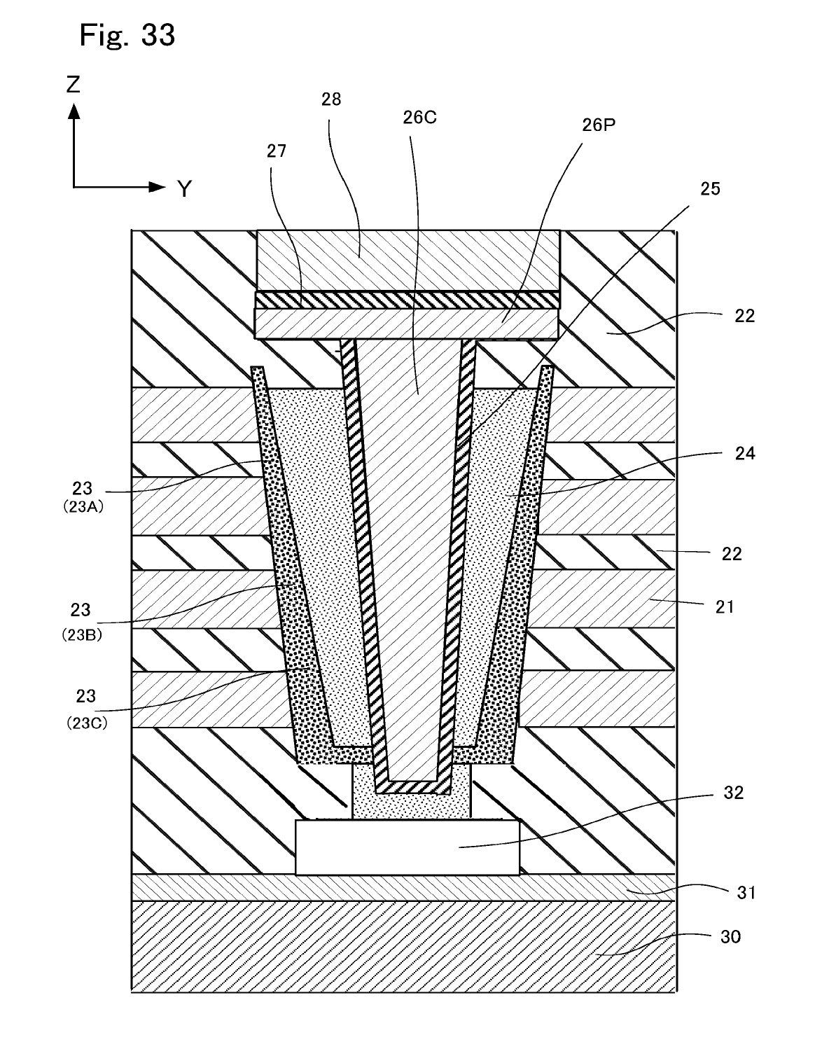

FIG. 33 is a schematic cross-sectional view illustrating a part including the plurality of memory cells MC in the memory cell array 11 according to the fourth embodiment. In this embodiment, the memory cell MC includes the variable resistance film 23 whose film thickness consecutively changes.

### Manufacturing Method

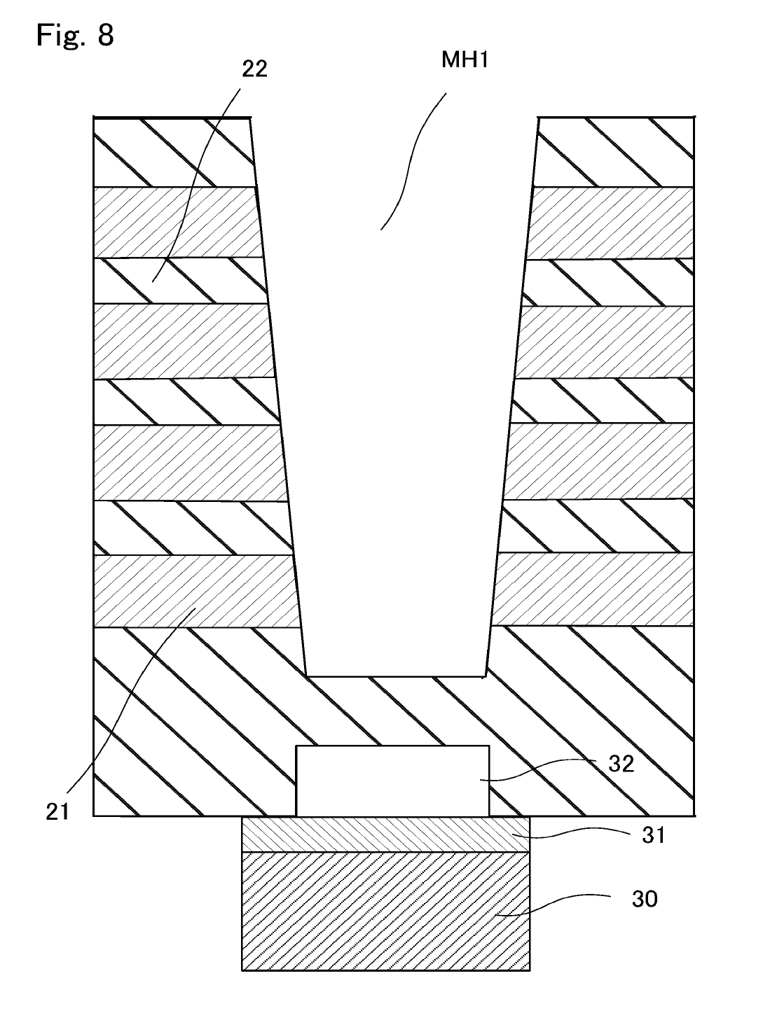

The following describes a method for manufacturing a nonvolatile semiconductor memory device according to the first embodiment with reference to FIG. 8 to FIG. 17.

On the substrate 20 (not illustrated), the conducting layer 30 (the global bit line GBL), the barrier layer 31, and the conducting layer 32 are formed via an insulating layer (not illustrated). The interlayer insulating layer 22 is formed on the conducting layer 32. Additionally, the conducting layers 21 (function as the word lines WL) and the interlayer insulating layers 22 are laminated in alternation by the number of required layers of the memory cell array 11 on the interlayer insulating layer 22. FIG. 8 illustrates the state of forming a first memory hole MH1, which penetrates this laminated body, by reactive ion etching method (RIE) or a similar method. To bore the hole of the first memory hole MH1, the drawing describes only the four layers as the number of the conducting layers 21. However, to increase the degree of integration of the actual elements, the extremely large number of layers is laminated. Therefore, boring the hole with high aspect ratio is necessary. Accordingly, the vertical process generates a vertical displacement at the deep part of the hole. Therefore, the drawing describes the first memory hole MH1 not the vertical cylindrical shape but is a structure having a tapered shape.

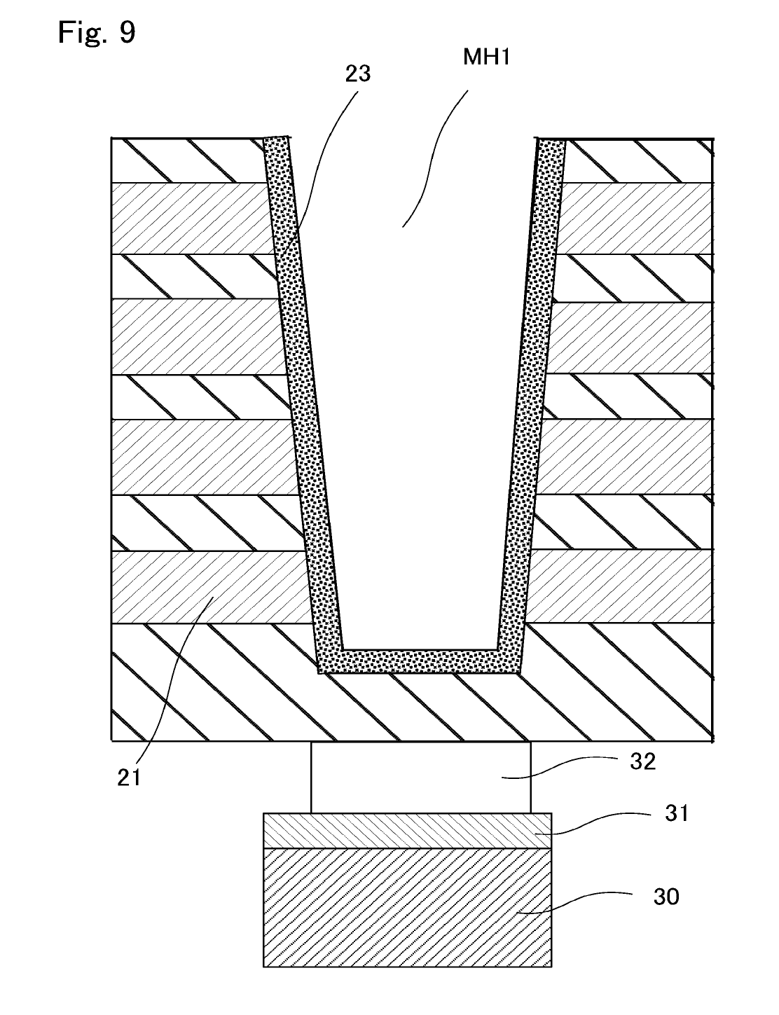

Next, as illustrated in FIG. 9, the variable resistance film 23, which is made of a metal oxide film, such as hafnium oxide (HfOx), is formed along the inner wall of the first memory hole MH1 by a CVD method or a similar method.

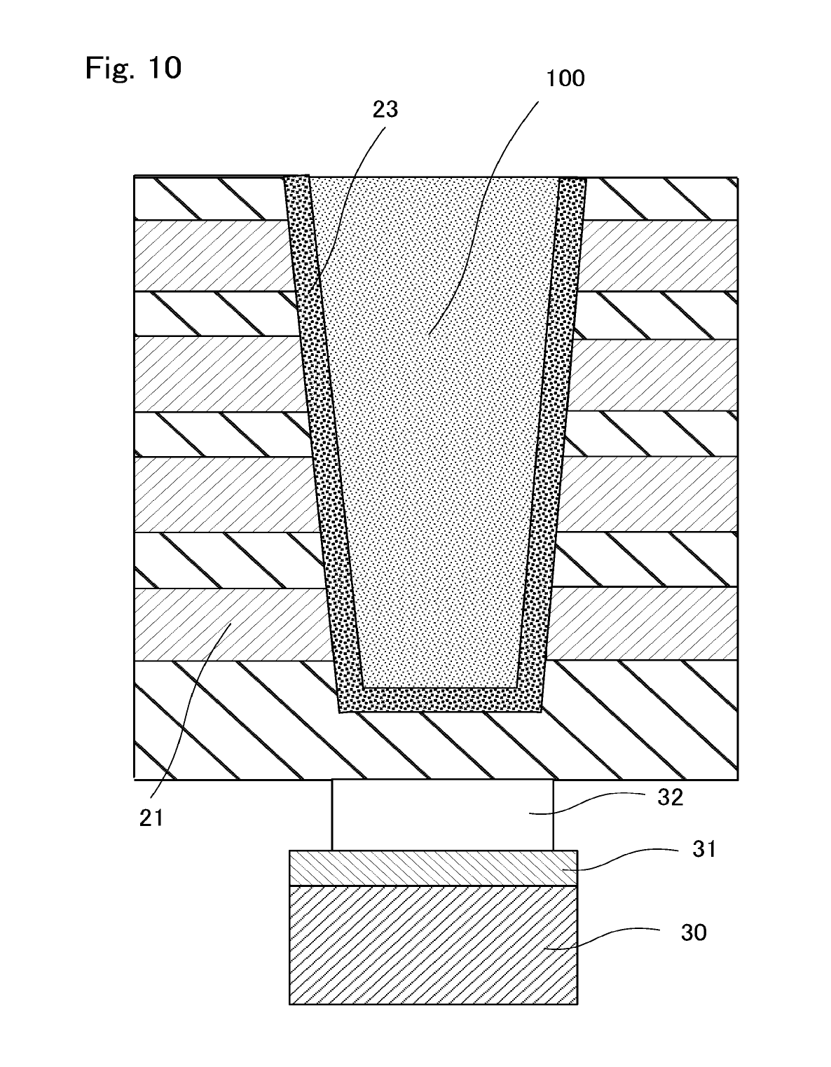

Next, as illustrated in FIG. 10, a photoresist 100 is filled so as to embed the first memory hole MH1.

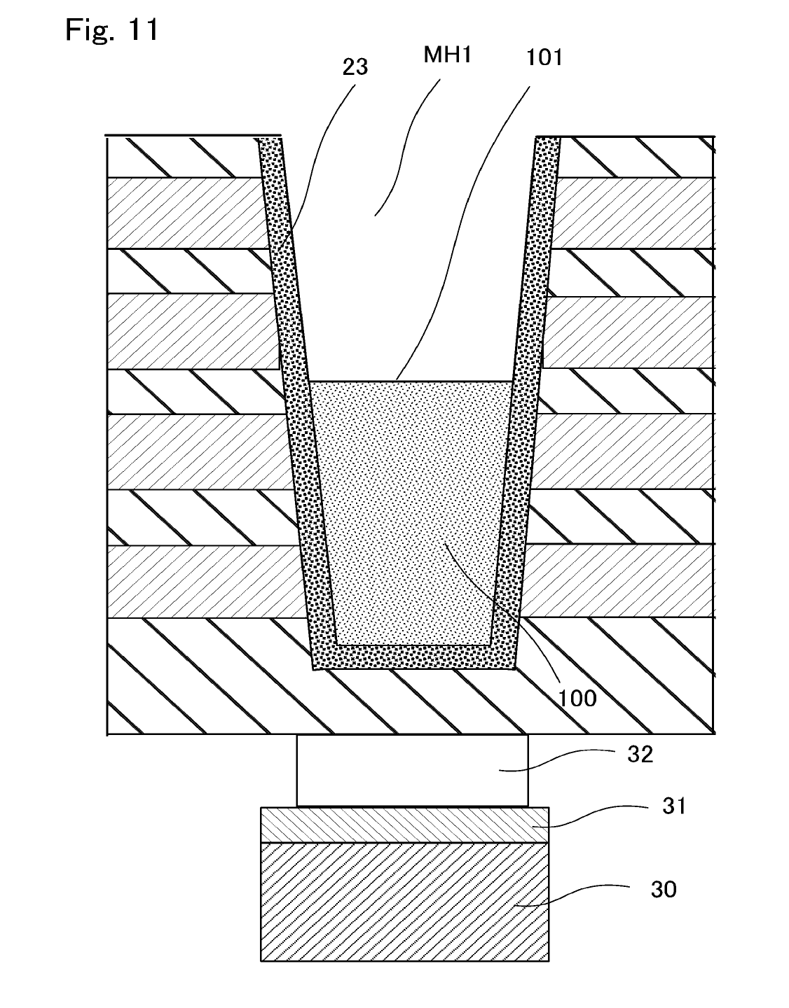

Thereafter, as illustrated in FIG. 11, the photoresist 100 is etched with oxygen plasma to dig down up to a depth 101. The photoresist 100 covers only the part at which the variable resistance film 23 is desired to remain thick.

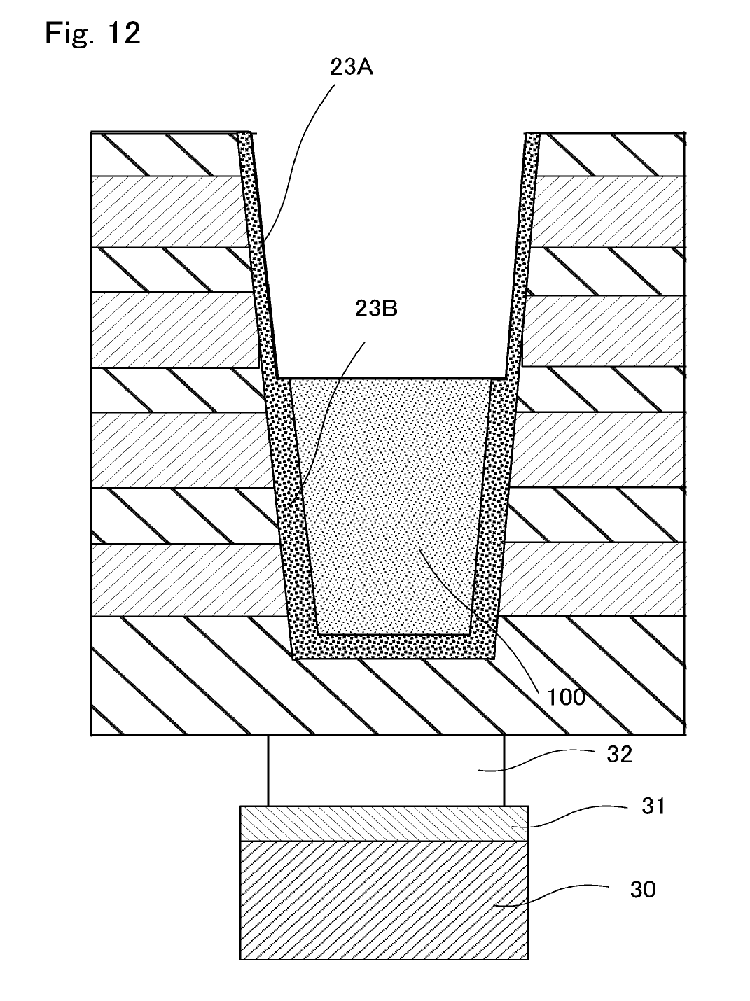

Next, as illustrated in FIG. 12, the region at which the variable resistance film 23 is exposed is dry-etched using BCL₃ plasma or a similar plasma, which allows selective etching to hafnium oxide, to selectively thin the variable resistance film 23. The part where the film thickness of the variable resistance film 23 remains intact is expressed as the variable resistance film (the first part 23B). The thinned part is referred to as the variable resistance film (the second part 23A).

Needless to say, this etching process changes gas according to the material of the variable resistance film 23 to perform more accurate selective etching.

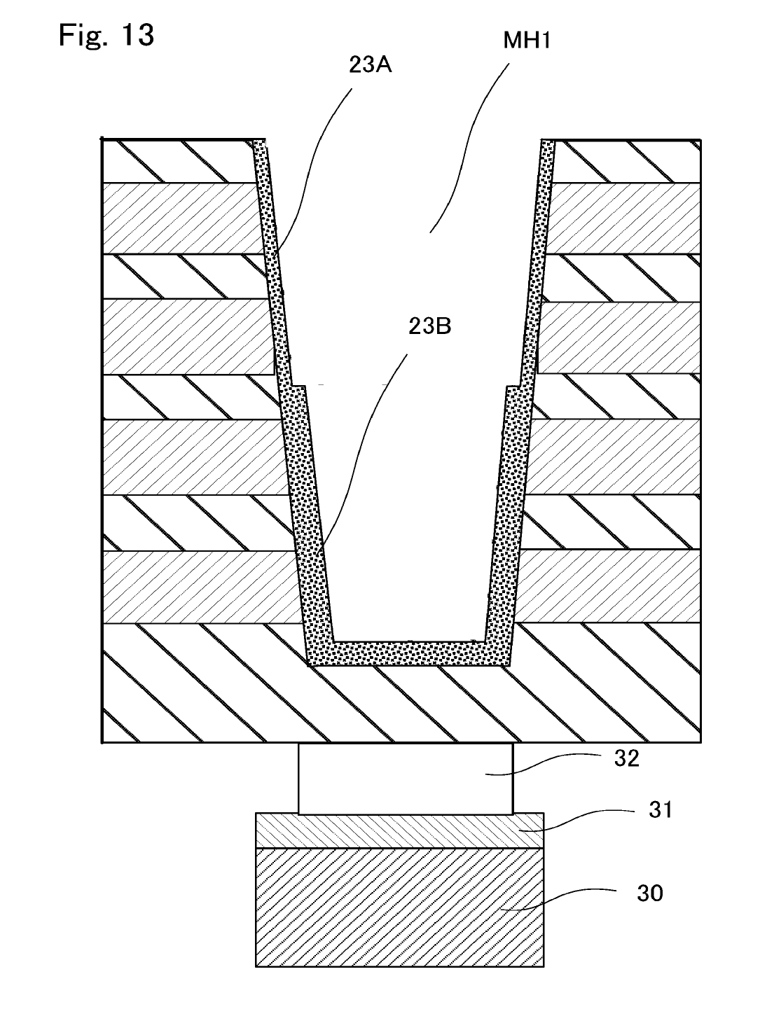

Next, as illustrated in FIG. 13, after the selective etching of the variable resistance film 23, the photoresist 100 is removed to expose the variable resistance film 23.

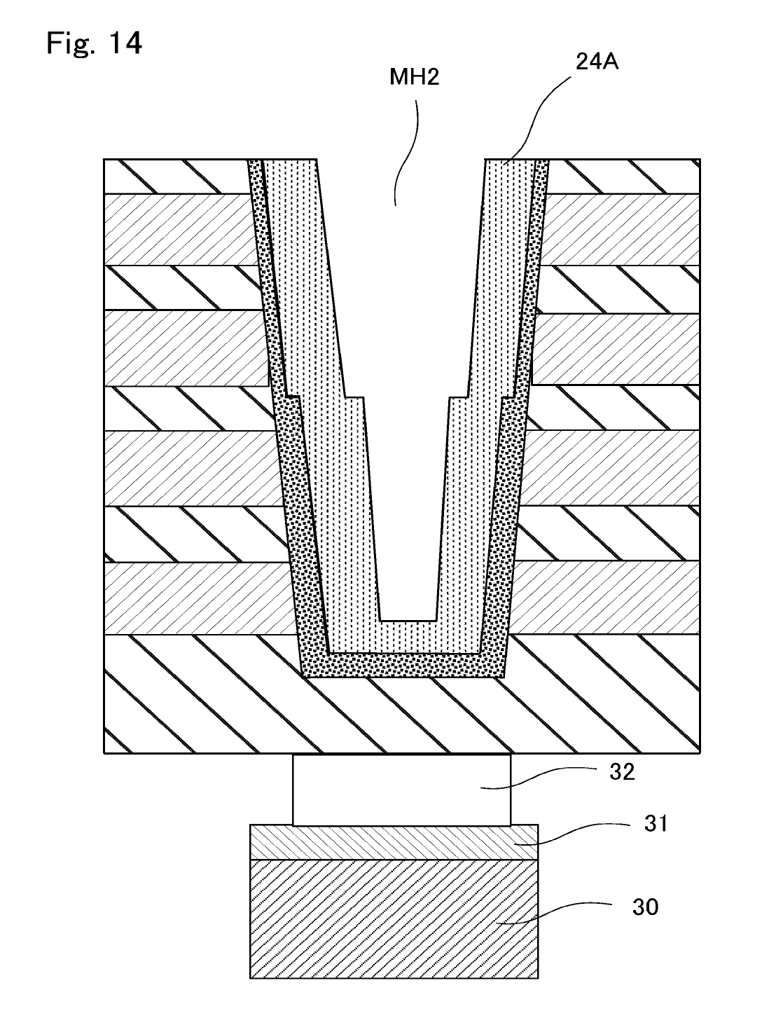

Next, as illustrated in FIG. 14, a film is formed with non-doped polysilicon or N⁻ type polysilicon of low impurities by the CVD method or a similar method. Thus, a semiconductor layer 24A (functions as the local bit line LBL) is formed. The semiconductor layer 24A is configured to completely cover the variable resistance film 23. This semiconductor layer 24A serves as a protective film that prevents the variable resistance film 23 from deteriorating in the etching process of forming a second memory hole MH2. In the embodiment, the electrical characteristic of the semiconductor layer 24A is adjusted to be an impurity concentration appropriate for a normally-off transistor.

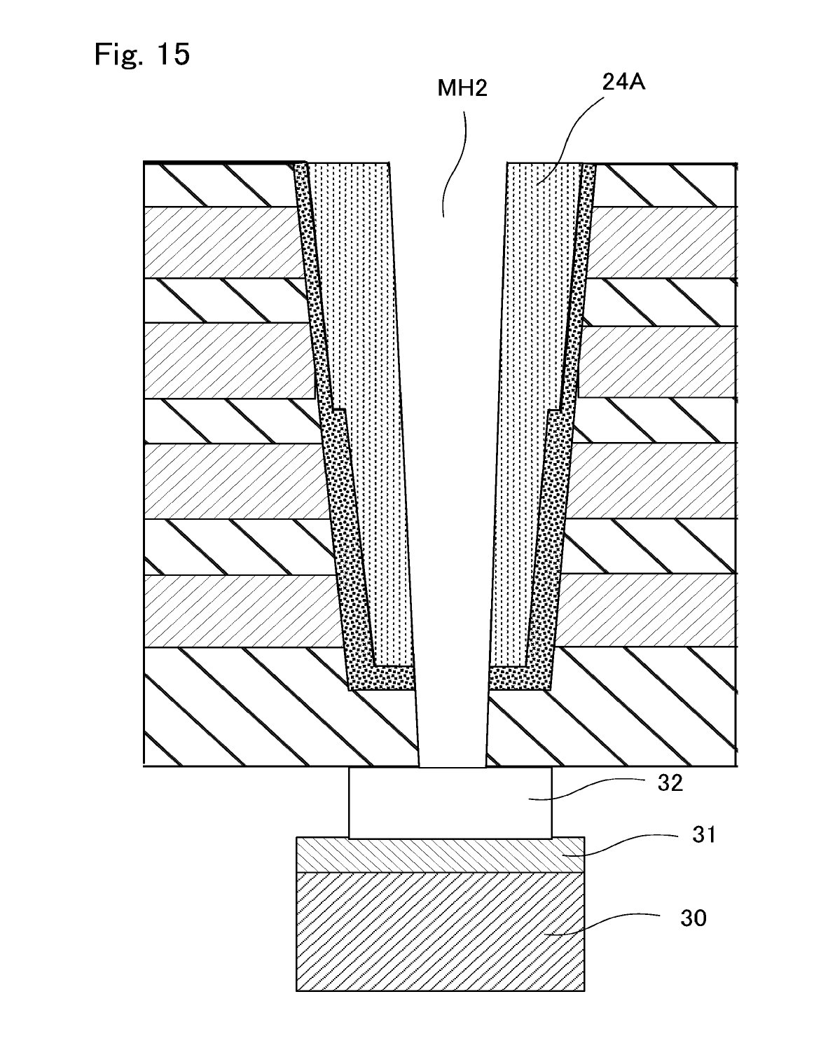

Next, as illustrated in FIG. 15, using an RIE method or a similar method, the second memory hole MH2 is formed. This second memory hole MH2 penetrates the bottom surfaces of the semiconductor layer 24A and the variable resistance film 23 and reaches up to the top surface of the conducting layer 32.

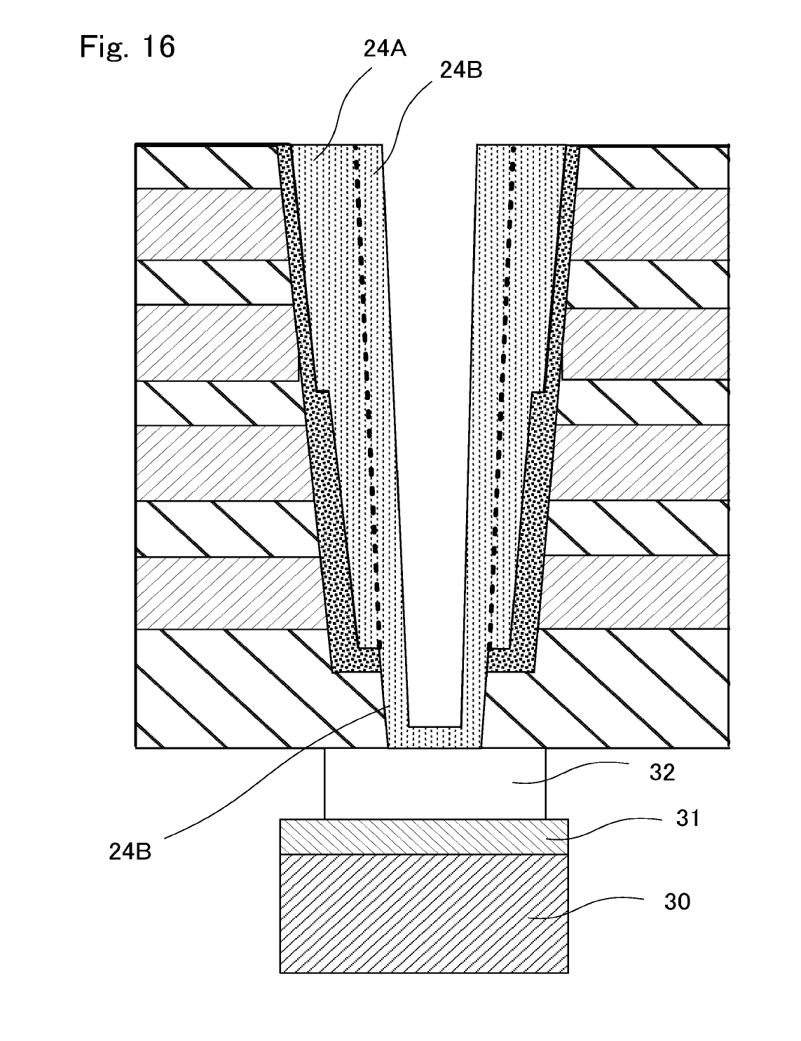

Next, as illustrated in FIG. 16, along the inner sidewall of the second memory hole MH2, a semiconductor layer 24B is formed by the CVD method or a similar method. This semiconductor layer 24B uses the material identical to the semiconductor layer 24A, which is described in the process of FIG. 14. FIG. 16 separates the boundary between the semiconductor layer 24A and the semiconductor layer 24B by dotted line for explanation. However, the semiconductor layer 24A and the semiconductor layer 24B are made of the identical material and are described as the semiconductor layer 24 without distinction in the following drawings. This forms the semiconductor layer 24 opposed to the side surfaces of the conducting layers 21 via the variable resistance film 23 and has an approximately U shape viewed in the Y-Z plane. The bottom portion of this semiconductor layer 24B is in contact with the conducting layer 32.

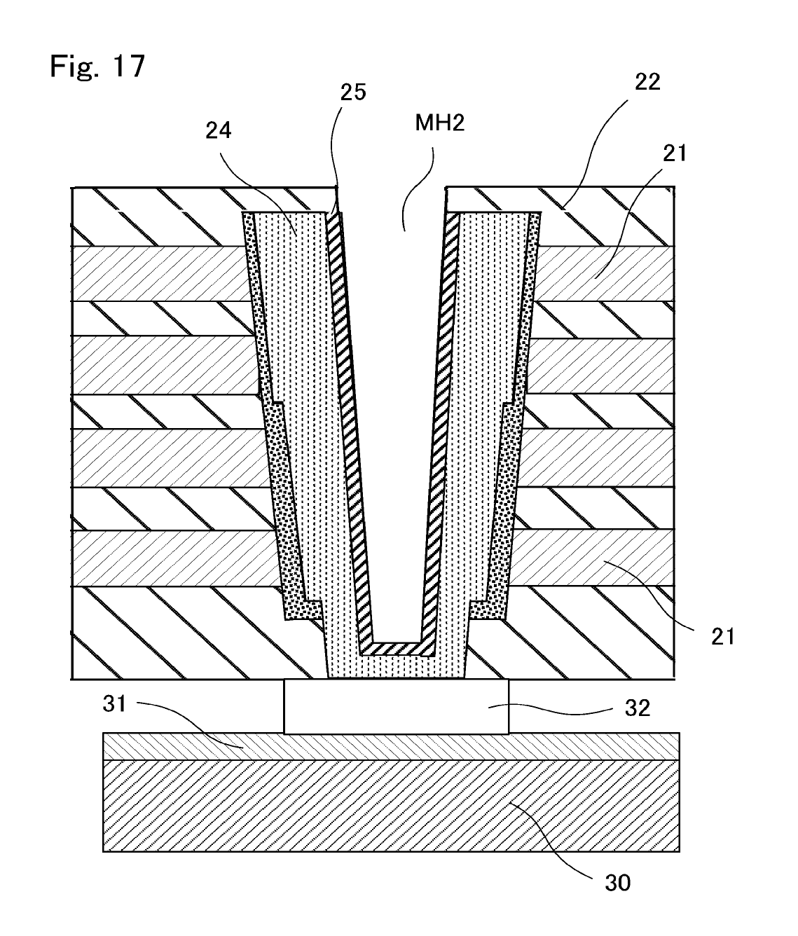

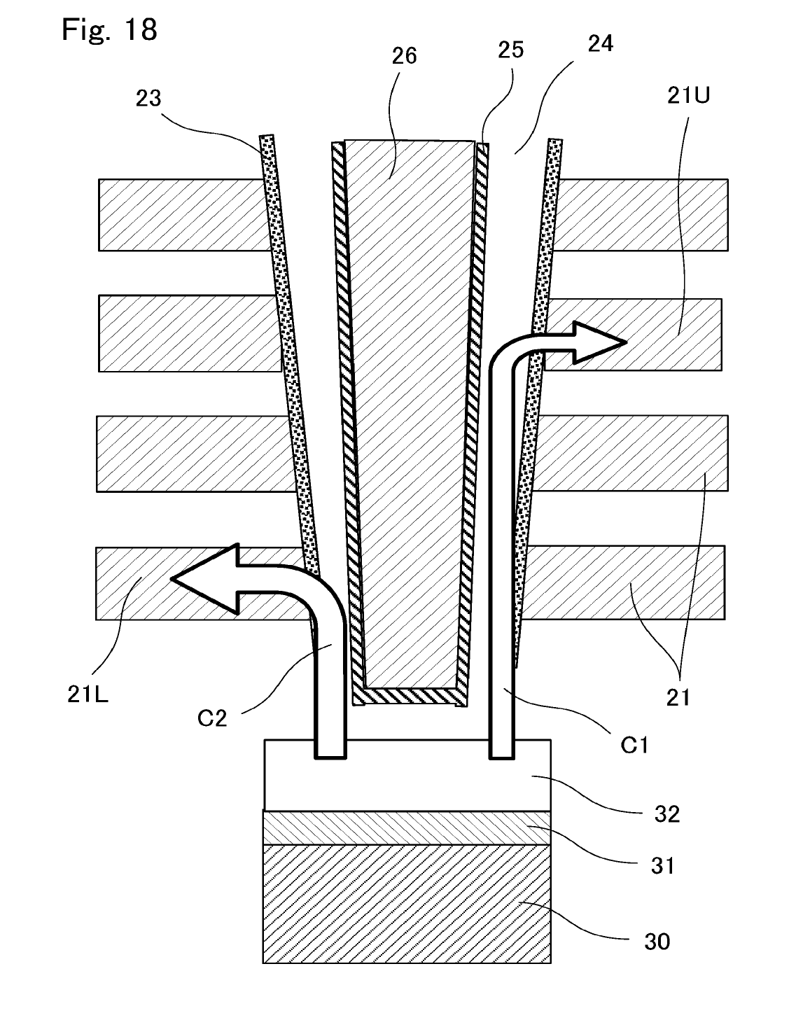

Next, as illustrated in FIG. 17, the gate insulating film 25 made of an insulating material, such as silicon oxide (SiO_{X}) and alumina (Al_{X}O_{Y}), is formed along the inner sidewall of the semiconductor layer 24 by the CVD or a similar method.

Finally, N⁺ type polysilicon or titanium nitride, which will be the gate electrode GE, is filled to form the conducting layer 26C and the conducting layer 26P. Further, above the semiconductor layer 26P, the barrier layer 27, which is made of titanium silicide or a similar material, and the conducting layer 28 (the gate line GL), which is made of tungsten (W) or a similar material, are sequentially formed. In the next process, the interlayer insulating layer 22 made of silicon oxide (SiO_{X}) or a similar material is formed, thus obtaining the configuration in FIG. 5.

Thus, through the process of selective etching of the variable resistance film 23, the variable resistance film 23 having different thicknesses in the Z direction, which is as illustrated in FIG. 5, can be formed.

### COMPARATIVE EXAMPLE

The following describes a configuration and a memory access operation of a nonvolatile semiconductor memory device according to Comparative Example with reference to FIG. 18.

With the above-described first embodiment, the film thickness of the variable resistance film 23 has the different thicknesses in the Z-axis direction. That is, as illustrated in FIG. 5 or a similar drawing, the film thickness of the variable resistance film 23 close to the conducting layer 30 (the global bit line GBL) is thick, and the film thickness of the variable resistance film 23 far from the conducting layer 30 is thin.

In contrast to this, the film thickness of the variable resistance film 23 of the nonvolatile semiconductor memory device according to Comparative Example has the identical thickness at the parts opposed to any conducting layer 21 (word lines WL) laminated in the Z-axis direction. In other words, the resistance values of the variable resistive elements VR are approximately identical in any memory cell.

The following describes a selection process of two cases in this Comparative Example using FIG. 18. The first case is an access operation in the case where the selected conducting layer 21 is far from the conducting layer 30. This case is expressed as an access to the third conducting layer 21U from the bottom. The arrow C1 expresses the current path during the access. The second case is an access operation in the case where the selected conducting layer 21 is close to the conducting layer 30. This case is expressed as an access to the lowermost conducting layer 21L on the lowermost layer in FIG. 18. The arrow C2 expresses the current path during the access.

As well as in the memory cell array 11 in Comparative Example, the semiconductor layer 24 (the local bit line LBL) has the tapered shape in the Z-axis direction by processes of forming the first memory hole MH1 and the second memory hole MH2 or a similar process. The resistance value of the semiconductor layer 24 is large at the thin part.

In the case where the accessed conducting layer 21 (the word line WL) is far from the conducting layer 30 (the global bit line GBL), the flowing current needs to pass through the thin bottom portion of the semiconductor layer 24 and the high resistance part over a long range. Consequently, the current value decreases. The thin arrow C1 on the right side expresses this state.

In contrast to this, the second access example is the case where the selected conducting layer 21 is close to the conducting layer 30. The thick arrow C2 expresses the current path in this access example. Even if the resistance value is high at the thin part of the semiconductor layer 24 having the tapered shape, since the current path is short, compared with the first selection example far from the conducting layer 30, a large current flows. Depending on the position of the layer of the conducting layer 21 (the word line WL) thus accessed, an operating current changes. This fails to configure the preferable nonvolatile semiconductor memory device.

### Second Embodiment

Next, the following describes a nonvolatile semiconductor memory device according to the second embodiment.

### Configuration

The overall configuration of the nonvolatile semiconductor memory device according to the second embodiment is identical to the overall configuration of the first embodiment including the reference numerals in the block diagram illustrated in FIG. 1. Accordingly, the description is omitted here.

An exemplary equivalent circuit diagram of the memory cell array 11 in the nonvolatile semiconductor memory device according to the second embodiment is identical to the case of FIG. 2, which illustrates the exemplary equivalent circuit diagram of the memory cell array 11 according to the first embodiment, including the reference numerals. Similarly, the content described about the operation of the memory cell array 11 according to the first embodiment with reference to FIG. 2 is identical to the memory cell array 11 according to this embodiment. Accordingly, the explanation is omitted here.

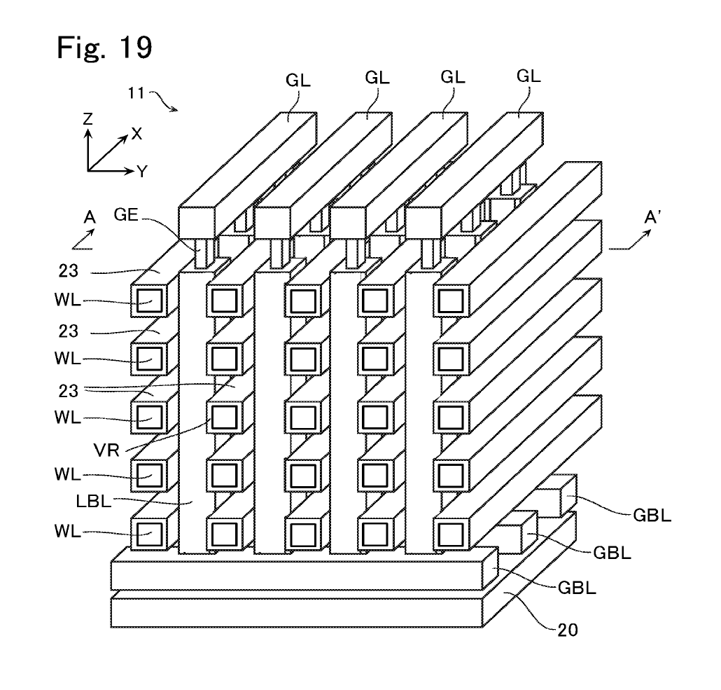

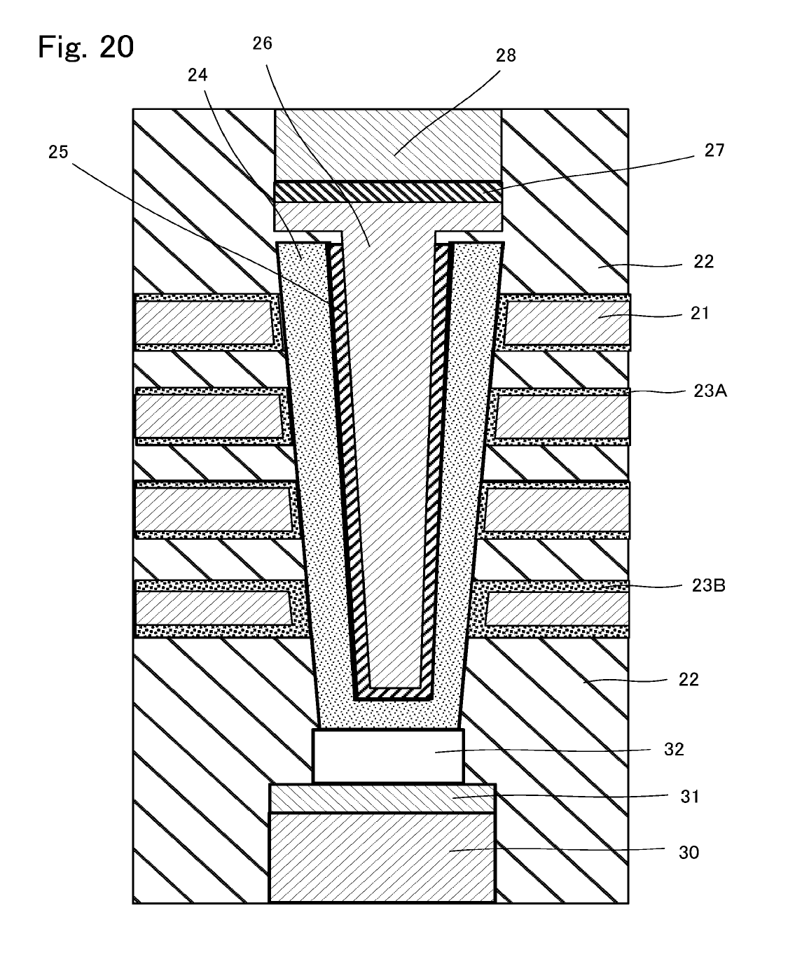

Next, the following describes the schematic configuration of the memory cell array 11 according to the second embodiment with reference to FIG. 19 and FIG. 20. FIG. 19 is a perspective view illustrating an exemplary laminated structure of the memory cell array 11. FIG. 20 is a schematic cross-sectional view illustrating a part including the plurality of memory cells MC in the memory cell array 11 according to this embodiment.

As illustrated in FIG. 19, the word lines WL are parallel to the surface of the substrate 20. The plurality of word lines WL have a length in the X direction and are disposed in the Y direction, which is perpendicular to the X direction. Although not illustrated, similar to the case illustrated in FIG. 4A and FIG. 4B, these word lines WL have two sets of comb shape viewed from the Z direction. The teeth of the combs are relatively nested to one another.

In FIG. 19, the five layers of the word lines WL are laminated in the Z direction; however, in FIG. 20, the word lines WL are described as four laminated layers.

As illustrated in FIG. 19, the variable resistance film 23 is formed so as to cover the top surface, the bottom surface, and the side surfaces of the word line WL. This is the difference between the memory cell array 11 according to the second embodiment and the memory cell array 11 according to the first embodiment.

The local bit lines LBL extend in a columnar manner in the vertical direction (the Z-axis direction) with respect to the substrate 20. The local bit lines LBL are disposed in an array shape in the X direction and the Y direction (The example in FIG. 19 illustrates these local bit lines LBL of 3×4=12 pieces). The local bit lines LBL are electrically connected to the global bit lines GBL on the substrate 20 side.

In FIG. 19, the memory cell array 11 is consisted of three components; the word lines WL, the local bit lines LBL, and the variable resistance films 23 disposed between both. The local bit lines LBL extend in the Z direction, which are perpendicular to the substrate 20. The word lines WL extend in the X direction. Both side surfaces of the one local bit line LBL in the Y direction, the word lines WL contact via the variable resistance films 23. The variable resistance films 23 at the intersection portions of these local bit lines LBL and word lines WL constitute the variable resistive elements VR. A large number of the word lines WL are laminated on the substrate 20. Accordingly, the memory cell array 11 is formed by lamination at predetermined pitches in the Z direction perpendicular to the substrate 20.

As illustrated in FIG. 19, the global bit lines GBL are disposed on the substrate 20. The global bit lines GBL extend in the Y direction and are arrayed at predetermined pitches in the X direction.

As illustrated in FIG. 19, the columnar-shaped local bit lines LBL, which are made of semiconductor and extend in the Z direction, are disposed on the side surfaces of the variable resistance films 23 on the opposite side from the word lines WL. That is, the local bit lines LBL are in contact with the word lines WL via the variable resistance films 23. The local bit lines LBL are disposed in a matrix in the X direction and the Y direction.

The semiconductor, which constitutes the local bit line LBL, may be made of polysilicon to which impurities such as phosphorus (P), boron (B), or arsenic (As) is added to the extent that the normally-off transistor can be formed, as well as non-doped polysilicon to which impurities are not added.

With the nonvolatile semiconductor memory device of the embodiment having the above-described configuration, the memory cells MC including the variable resistive elements VR are disposed at the portions where the word lines WL intersect with the local bit lines LBL.

As illustrated in FIG. 19, the plurality of local bit lines LBL are connected in common to the one global bit line GBL at the lower ends in the Z direction. The global bit lines GBL extend in the Y direction and are disposed on the substrate 20 at predetermined pitches in the X direction. The global bit line GBL is, for example, made of metal such as tungsten (W).

As illustrated in FIG. 19, the gate lines GL are disposed upward more than the word line WL on the uppermost layer. The gate lines GL extend in the X direction and are arrayed at predetermined pitches in the Y direction. As illustrated in FIG. 19, to the one gate line GL, the plurality of gate electrodes GE aligned in the X direction are connected in common.

The following further describes the configuration of the memory cell array 11 in details using FIG. 20. The variable resistance film 23 covers the side surface, the top surface, and the bottom surface of the conducting layer 21 (the word line WL). The plurality of conducting layers 21 (word lines WL) separated by the interlayer insulating layer 22 are laminated by the number of required layers for the memory cell array 11.

By penetrating the conducting layers 21 and the interlayer insulating layer 22, the semiconductor layer 24 (the local bit line LBL) is in ohmic contact with the conducting layer 30 (the global bit line GBL) via the conducting layer 32 and the barrier layer 31.

As illustrated in FIG. 20, in the semiconductor layer 24 (the local bit line LBL), the conducting layer 26 (the gate electrode GE) is coaxially embedded via the gate insulating film 25. The conducting layer 26 does not penetrate the bottom portion of the semiconductor layer 24.

The conducting layer 26 (the gate electrode GE) is electrically connected to the conducting layer 28 (the gate line GL) via the barrier layer 27.

The conducting layers 21 (the word lines WL) are opposed to the semiconductor layer 24 (the local bit line LBL) via the variable resistance films 23, which are the side surfaces of the conducting layers 21. This combination forms the variable resistive element VR.

As illustrated in FIG. 20, the variable resistance films 23 in the embodiment have the first thickness at the variable resistance films 23B, which are disposed on the conducting layers 21 (the word lines WL) on the substrate 20 side. The variable resistance films 23 have the second thickness at the variable resistance films 23A, which are disposed on the conducting layers 21 (the word lines WL) far from the substrate 20. The second thickness has a thickness smaller than the first thickness.

This difference in the thickness of the variable resistance films 23 becomes a difference in the resistance value of the variable resistive elements VR. As described in the first embodiment using FIG. 7, this difference in the resistance value allows achieving the nonvolatile semiconductor memory device excellent in uniformity of the current value during access to the memory cell array.

### Manufacturing Method

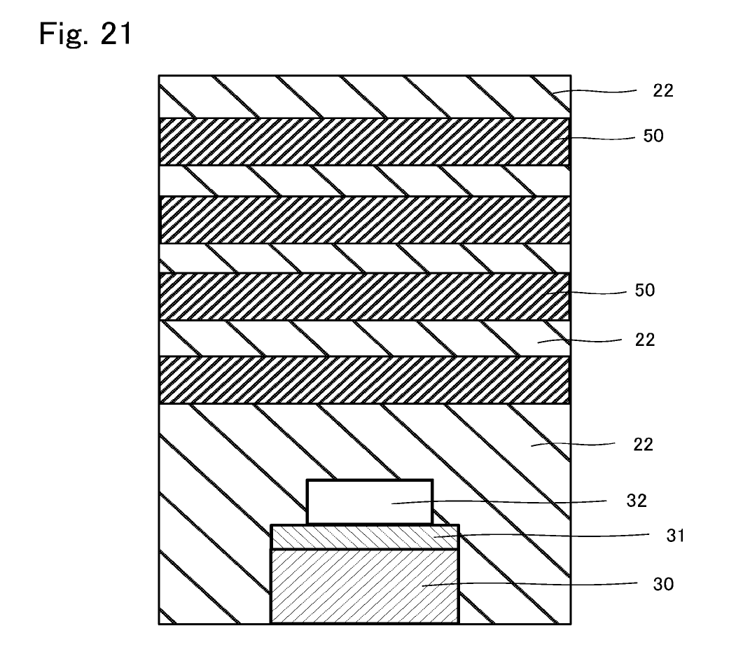

The following describes a method for manufacturing a nonvolatile semiconductor memory device according to the second embodiment with reference to FIG. 21 to FIG. 31.

First, as illustrated in FIG. 21, on a substrate (not illustrated), the conducting layer 30 (the global bit line GBL), the barrier layer 31, and the conducting layer 32 are formed via an insulating layer (not illustrated). The interlayer insulating layer 22, which is on the lowermost layer made of silicon oxide film (SiO_{X}) or a similar material, flats the surface.

Next, sacrificial layers 50 using a silicon nitride film (Si_{X}N_{Y}) or a similar material and the interlayer insulating layers 22 are laminated in alternation. The number of layers of these sacrificial layers 50 is configured to be identical to the number of required layers for the memory cell MC.

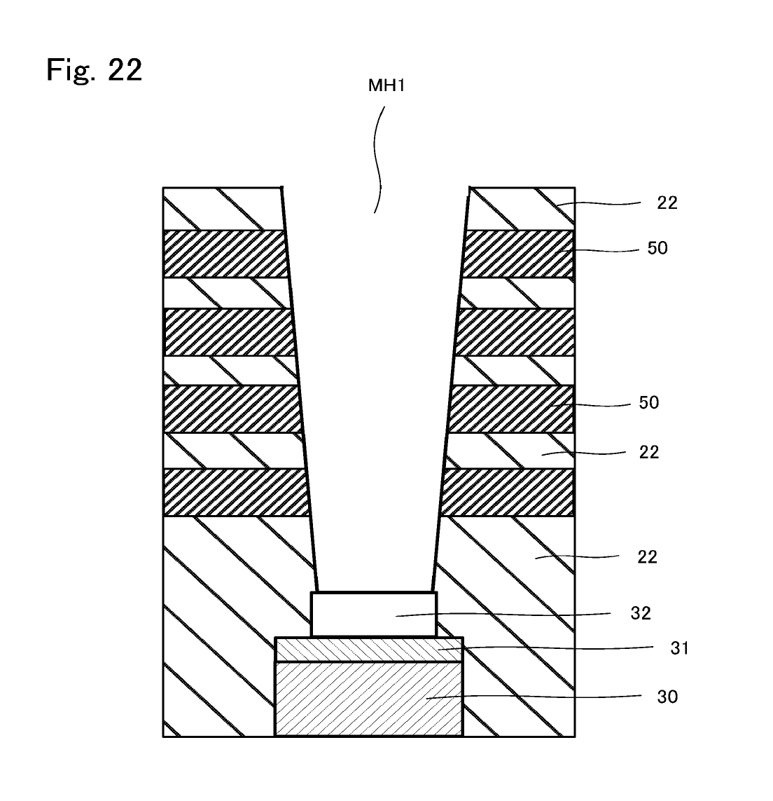

Next, as illustrated in FIG. 22, the first memory hole MH1 is formed by the RIE method or a similar method. This first memory hole MH1 is reached up to the conducting layer 32.

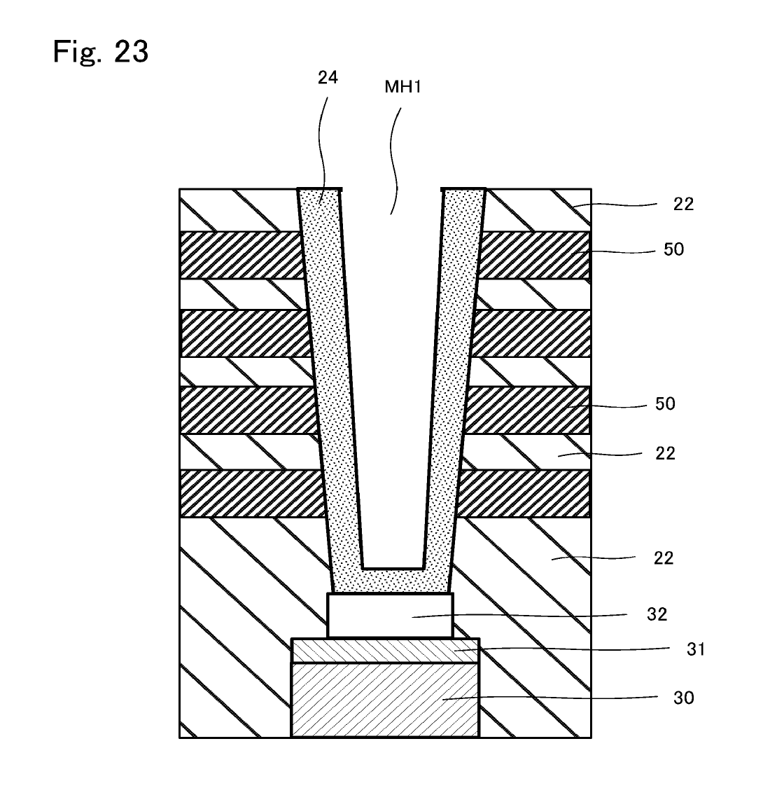

Further, as illustrated in FIG. 23, a film is formed with polysilicon for which the impurities are not doped or N⁻ type polysilicon of low impurities in the first memory hole MH1 by the CVD method or a similar method. Thus, the semiconductor layer 24 (functions as the local bit line LBL) is formed.

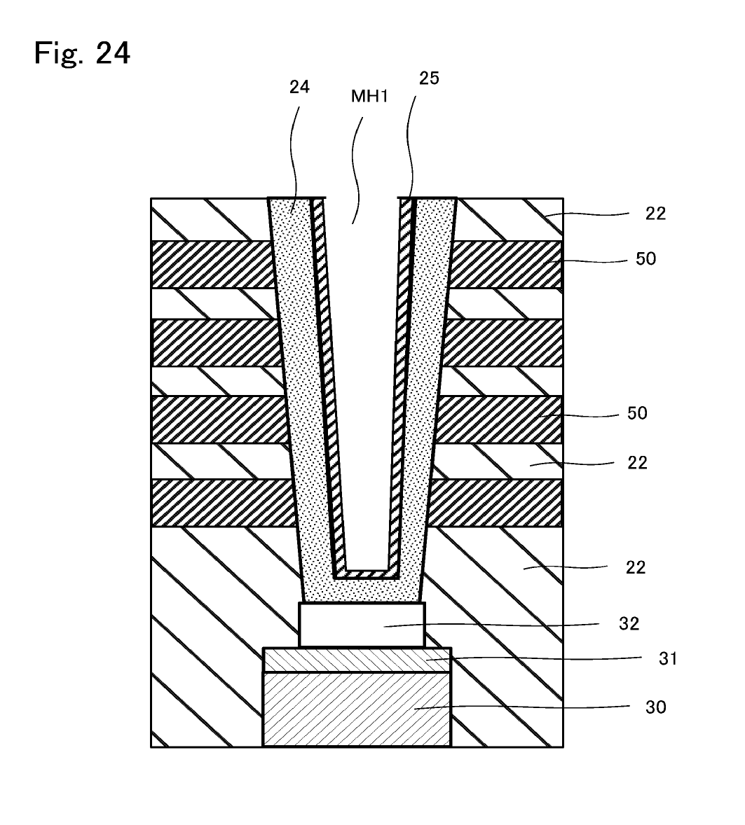

Next, as illustrated in FIG. 24, the gate insulating film 25 made of an insulating material, such as silicon oxide (SiO_{X}) and alumina (Al_{X}O_{Y}), is formed along the inner sidewall of the semiconductor layer 24 by the CVD or a similar method.

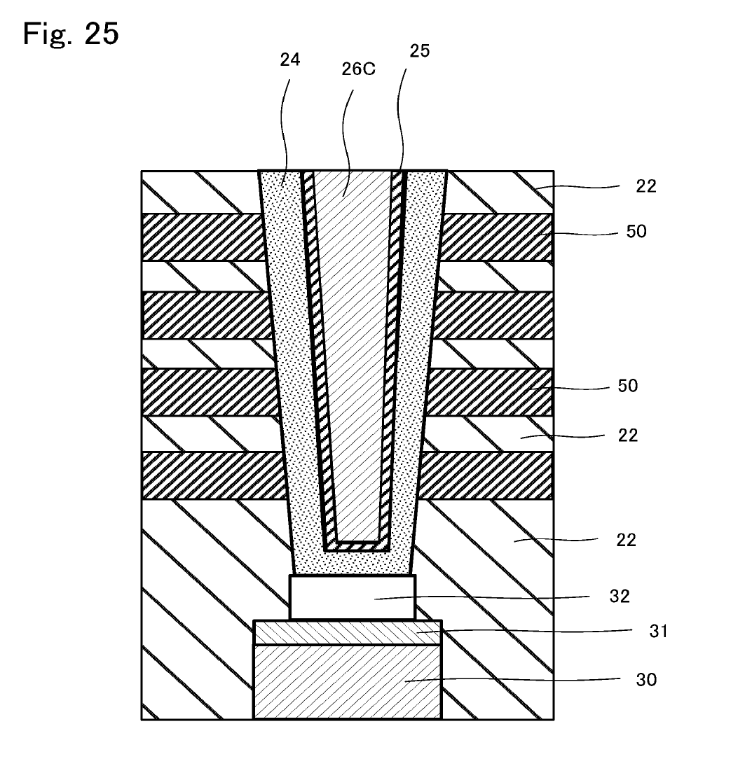

Further, as illustrated in FIG. 25, in the first memory hole MH1 surrounded by the gate insulating film 25, for example, high-concentration type polysilicon, titanium nitride (TiN), or a similar material is filled. Thus, the conducting layer 26C, which will be the gate electrode GE, is formed.

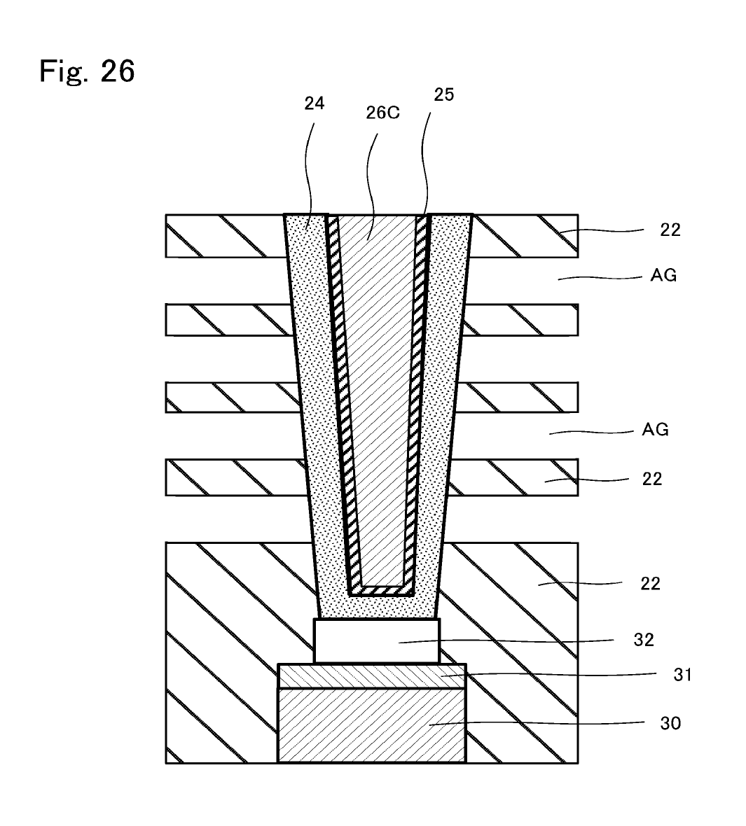

Next, as illustrated in FIG. 26, the sacrificial layers 50 made of a silicon nitride film (Si_{X}N_{Y}) are selectively removed using a hot phosphoric acid solution, thus forming air gaps AG. At this time, the semiconductor layer 24, the gate insulating film 25, and the conducting layer 26C, which becomes the gate electrode GE, become support pillars to prevent the remaining interlayer insulating layers 22, which are formed in the previous process, from collapsing. This prevents the air gap AG from squashing.

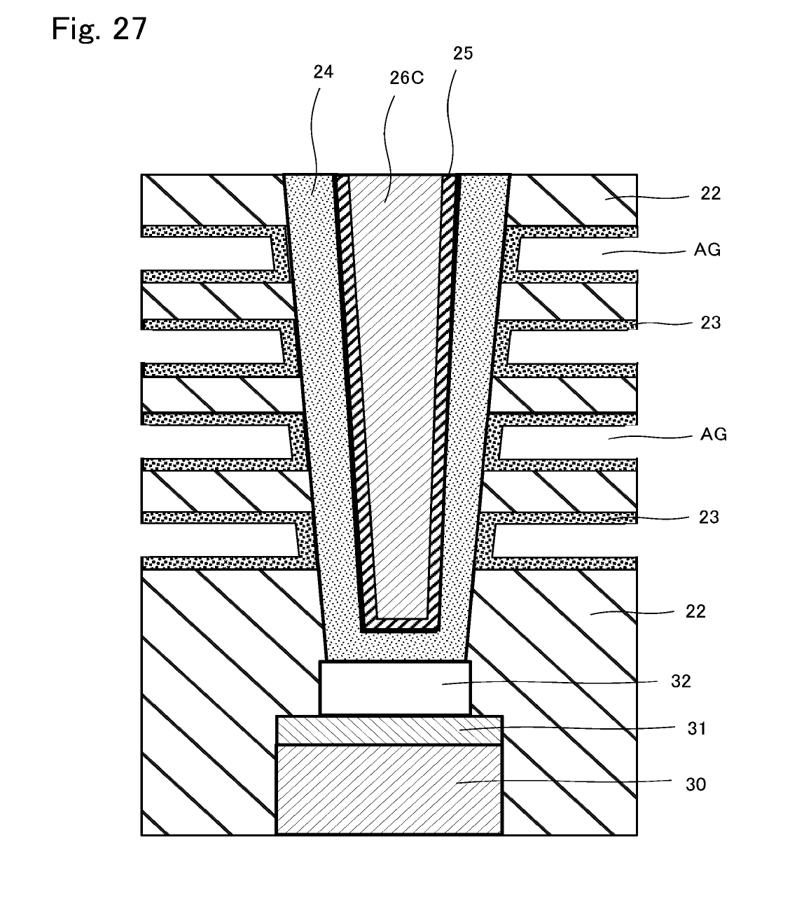

Subsequently, as illustrated in FIG. 27, the variable resistance films 23 are formed on the inner walls of the air gaps AG. The variable resistance film 23 is formed by performing the CVD method or a similar method on the metal oxide film made of hafnium oxide (HfO_{X}).

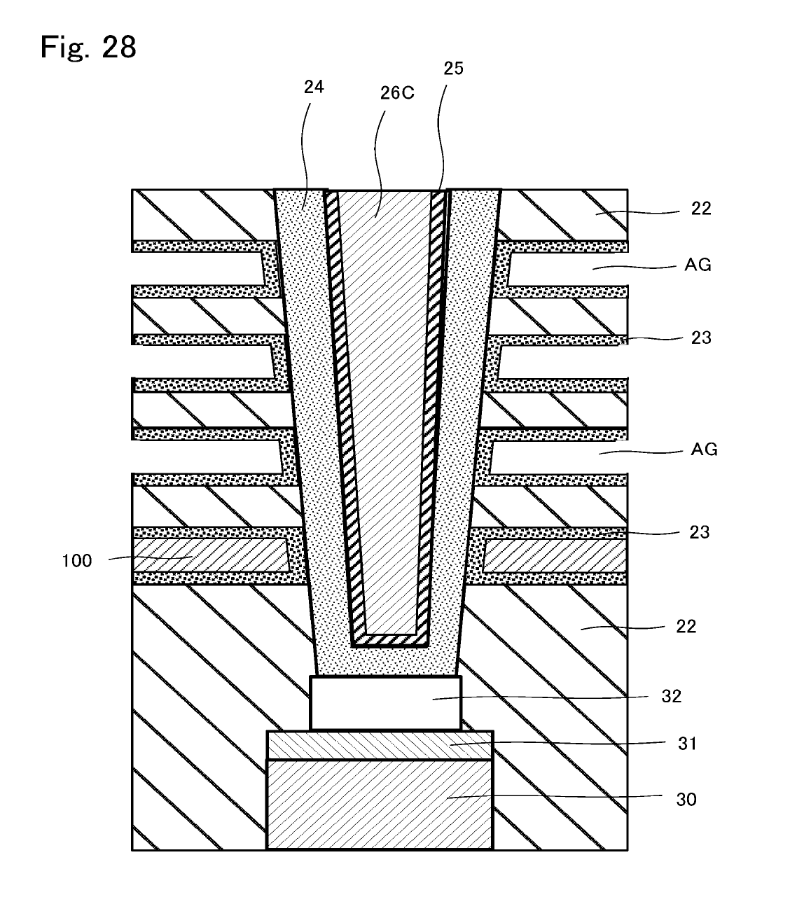

Next, as illustrated in FIG. 28, the photoresists 100 are filled to the inside of the air gaps AG on the side closest to the substrate. The photoresists 100 serve as protecting layers against etching performed for thinning the films of the variable resistance films 23, which is performed continuously.

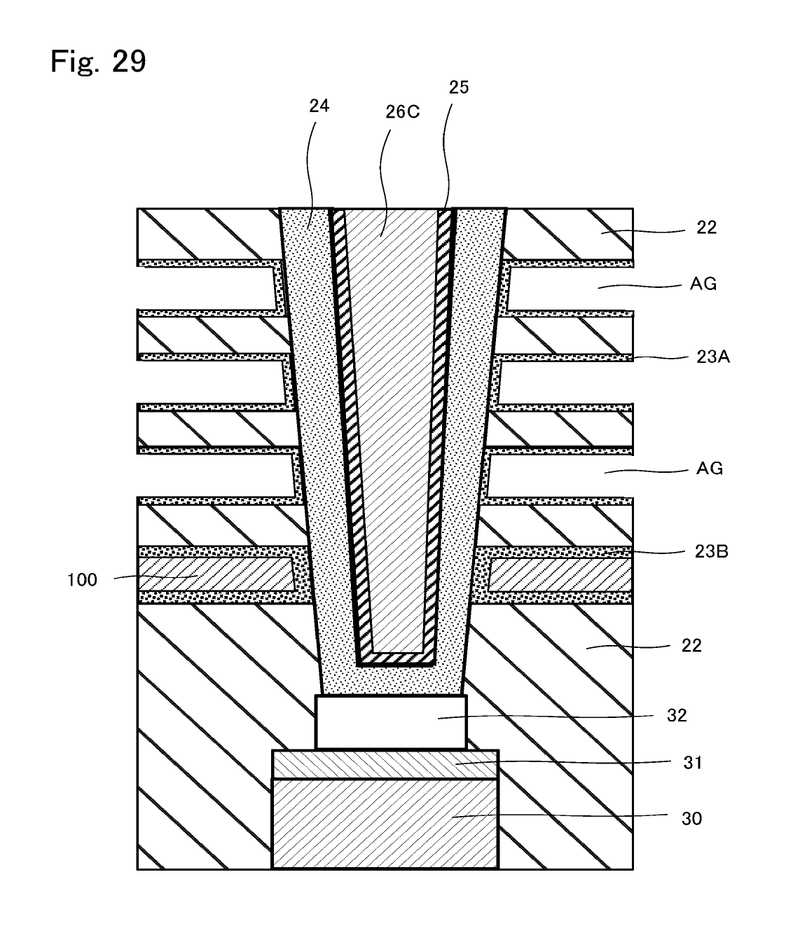

As illustrated in FIG. 29, the dry etching using BCL₃ plasma or a similar plasma is performed in this state to selectively thin the variable resistance films 23. In FIG. 29, the part where the film thickness of the variable resistance film 23 remains intact by the protecting layer is expressed as the first part 23B. The part thinned due to the absence of the protective film is denoted as the second part 23A.

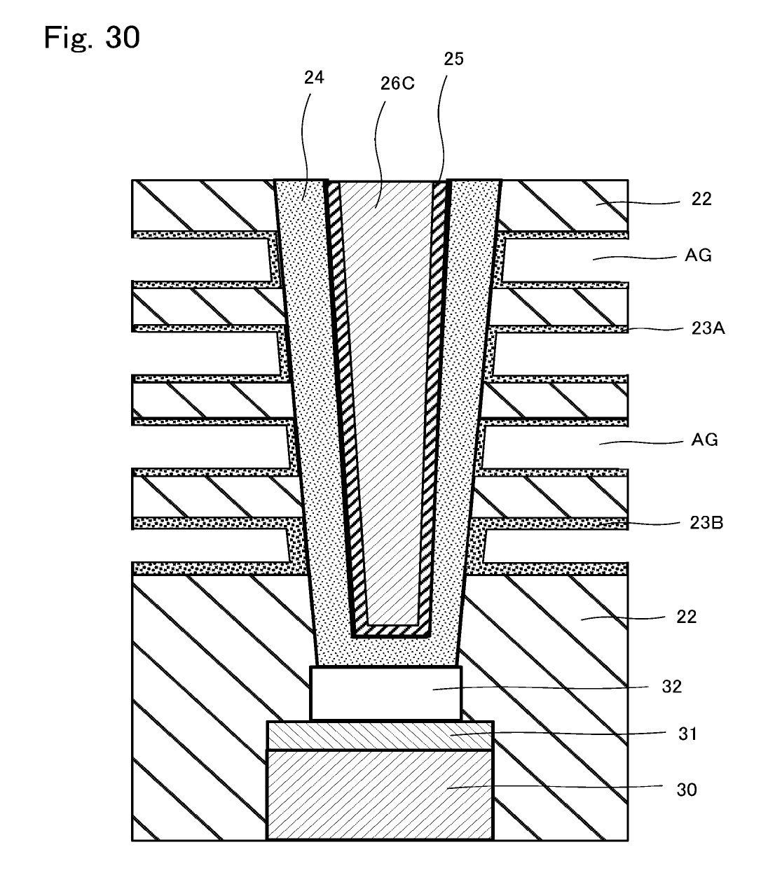

FIG. 30 illustrates a state where the photoresists 100 are removed from the air gaps AG on the lowermost layer.

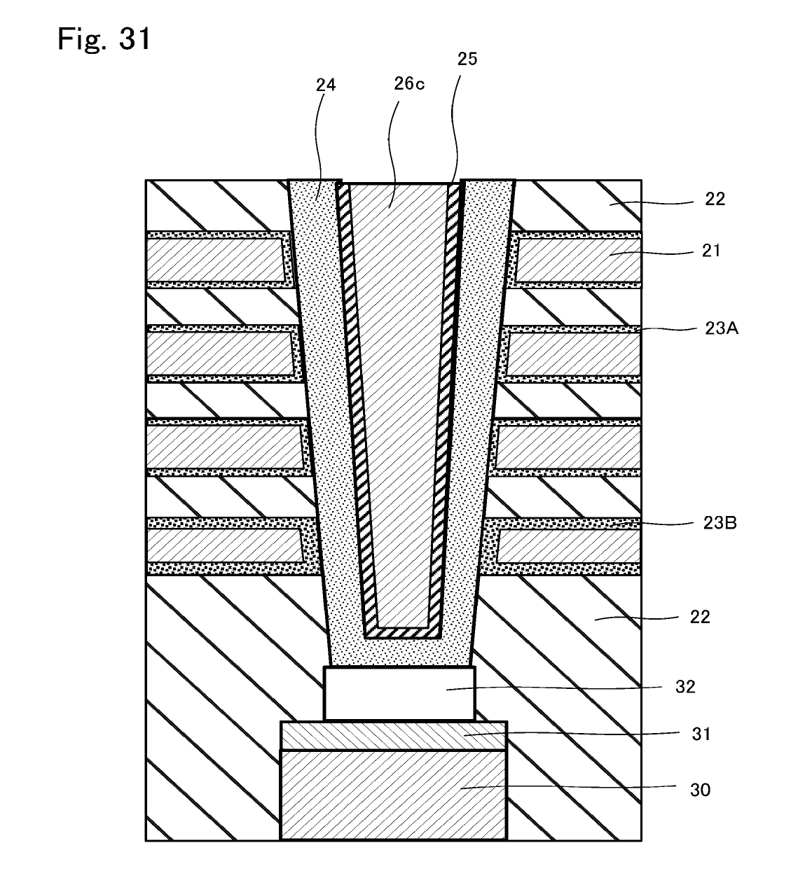

Next, metal such as tungsten (W) is embedded so as to embed the air gaps AG to which the variable resistance films 23 adhere. Thus, the laminated structure illustrated in FIG. 31 is formed.

Further, using the process similar to the first embodiment, the conducting layer 26P, which is made of the high-concentration n⁺ type polysilicon, titanium nitride (TiN), or a similar material and becomes the gate electrode GE, the barrier layer 27, which is made of titanium silicide (TiS) or a similar material, and the conducting layer 28 are formed. The layers are protected with the interlayer insulating layer 22, thus forming the memory cell array 11 for the nonvolatile semiconductor memory device, which is illustrated in FIG. 20.

### Third Embodiment

Next, the following describes a nonvolatile semiconductor memory device according to the third embodiment.

### Configuration

FIG. 32 illustrates a schematic cross-sectional view illustrating a part including the plurality of memory cells MC in the memory cell array 11 according to the third embodiment.

In the embodiment, the film thickness of the variable resistance film 23 changes into three levels. The upper layers have smaller film thickness, and the film thickness becomes the maximum on the bottom portion side. This configures a structure that allows further effectively restraining the variation of the current value during access compared with the above-described embodiments.

### Manufacturing Method

The first embodiment performs the protection with the photoresist and the etching process of the variable resistance film 23 once as the process of changing the film thickness of the variable resistance film 23. However, this embodiment forms the variable resistance film 23 with different film thicknesses in the multiple levels, which is as illustrated in FIG. 32, by performing the process twice. The processes other than the process are identical to the case of the first embodiment.

### Fourth Embodiment

Next, the following describes a nonvolatile semiconductor memory device according to the fourth embodiment. FIG. 33 illustrates a schematic cross-sectional view illustrating a part including the plurality of memory cells MC in the memory cell array 11 according to the fourth embodiment.

In the embodiment, the film thickness of the variable resistance film 23 has the shape of changing to be thin in the Z-axis direction. This configures a structure that effectively restrains the variation of the current value during access.

### Manufacturing Method

The first embodiment performs the protection with the photoresist and the etching process of the variable resistance film 23 once as the process of changing the film thickness of the variable resistance film 23. However, this embodiment uses the metal oxide film made of hafnium oxide (HfO_{X}) to form the variable resistance film 23 on the surface of the first memory hole MH1. After that, the etching is performed directly without using a protecting layer, such as a photoresist. For the etching, a barrel type plasma etching apparatus is used, and operating conditions where isotropy of etching becomes high are selected. The process used here is an etching method that does not have directionality. Accordingly, the etching speed is fast at a region of shallow hole while the etching speed is slow at a region of deep hole. Consequently, the shape of the variable resistance film 23 continuously changes. The variable resistance film 23 whose film thickness is thick on the substrate side and thin at a region far from the substrate is obtained.

### Fifth Embodiment

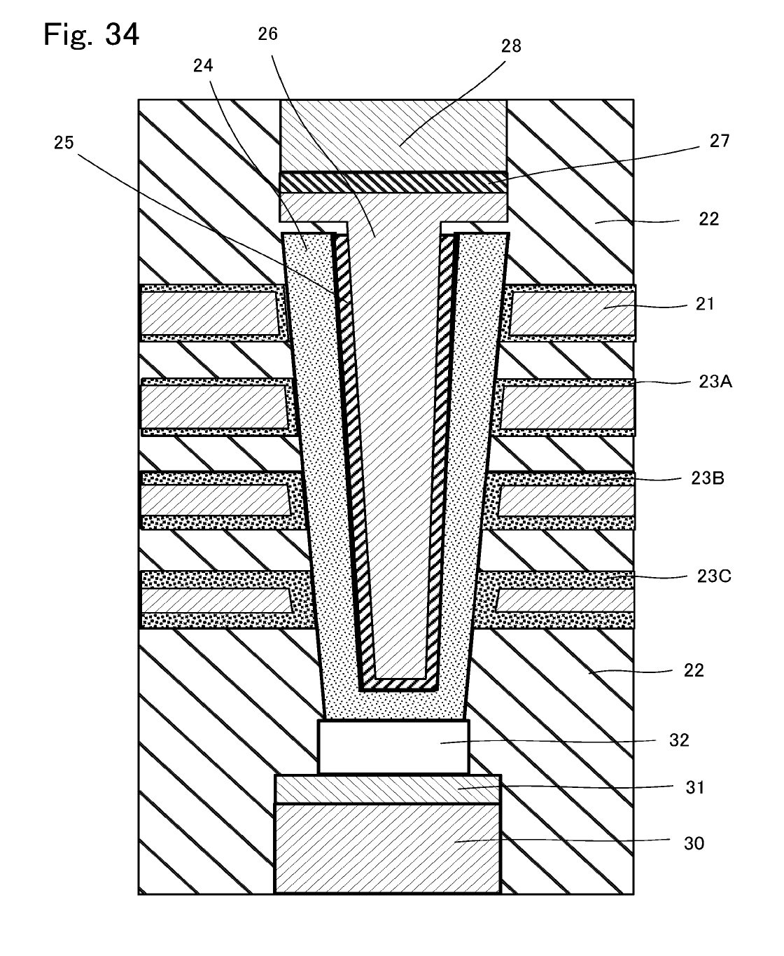

The following describes a nonvolatile semiconductor memory device according to the fifth embodiment. FIG. 34 illustrates a schematic cross-sectional view illustrating a part including the plurality of memory cells MC in the memory cell array 11 according to the fifth embodiment.

This embodiment is a modification of the memory cell array 11 according to the second embodiment. The memory cell array 11 of this embodiment has three different thicknesses of the variable resistance films 23, which are formed on the side surfaces, the top surfaces, and the bottom surfaces of the conducting layers 21 (the word lines WL) due to a difference in the layers where the conducting layers 21 (the word lines WL) are present. As away from the conducting layer 21 (the word line WL) closest to the substrate side in the drawing, the variable resistance films 23 are each sequentially expressed as 23C, 23B, and 23A. The magnitude relationship of the film thickness of the variable resistance films 23 is 23C>23B>23A.

By this relationship of the film thickness, regardless of the relationship of higher and lower of the layers of the memory cell array 11, good access operation is possible.

### Manufacturing Method

The process of protecting the variable resistance films 23 of the air gaps AG used to manufacture the memory cell array 11 according to the second embodiment with the photoresist is repeated twice. This obtains the memory cell array 11 of the embodiment, which is illustrated in FIG. 34.

### Others

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

For example, the above-described embodiments describe the so-called normally-off configuration. In the normally-off configuration, when the voltage is not applied to the semiconductor layer 24 (the local bit line LBL), which is the channel, the nonvolatile semiconductor memory device enters the Off state and when applied, the nonvolatile semiconductor memory device enters the On state. However, for example, in the case where the voltage can be independently applied to each local bit line LBL or a similar case, a so-called normally-on configuration that turns the nonvolatile semiconductor memory device to the Off state by applying the voltage to the local bit line LBL also can be used.

What is claimed is:

1. A nonvolatile semiconductor memory device, comprising
a memory cell array that includes a plurality of memory cell s, wherein
the memory cell array includes:
a plurality of conducting layers laminated at predetermined pitches in a first direction perpendicular to a substrate, the plurality of conducting layers extending in a second direction parallel to the substrate;
a semiconductor layer extending in the first direction;
a variable resistance film disposed at intersection points of the plurality of conducting layers and the semiconductor layer; and
a first wiring opposed to the semiconductor layer via a gate insulating film, the first wiring extending in the first direction,
the variable resistance film has a first thickness at a first part, the first thickness being in a direction from the plurality of conducting layers to the semiconductor layer, and
the variable resistance film has a second thickness at a second part, the second part being further from the substrate than the first part, the second thickness being smaller than the first thickness, the second thickness being in a direction from the plurality of conducting layers to the semiconductor layer.

2. The nonvolatile semiconductor memory device according to claim 1, wherein
the semiconductor layer has a columnar shape that surrounds a peripheral area of the first wiring.

3. The nonvolatile semiconductor memory device according to claim 1, wherein
the first wiring, the gate insulating film, and the semiconductor layer constitute a transistor, the first wiring serving as a gate, the semiconductor layer serving as a channel.

4. The nonvolatile semiconductor memory device according to claim 1, wherein
the memory cell array has a second wiring extending in the second direction, the second wiring being electrically connected to an upper portion of the first wiring.

5. The nonvolatile semiconductor memory device according to claim 4, wherein
the plurality of first wirings are disposed along the second direction, and
the second wiring is electrically connected to the plurality of first wirings in common, the first wirings being disposed along the second direction.

6. The nonvolatile semiconductor memory device according to claim 1, further comprising
a third wiring electrically connected to a lower end of the semiconductor layer, the third wiring extending in a third direction.

7. The nonvolatile semiconductor memory device according to claim 6, wherein
the third wiring is made of metal, and
a connection between the lower end of the semiconductor layer and the third wiring is an ohmic contact.

8. The nonvolatile semiconductor memory device according to claim 1, wherein
the conducting layer has a comb shape viewed from the first direction.

9. The nonvolatile semiconductor memory device according to claim 1, wherein
the variable resistance film is disposed from a sidewall of the first part to a sidewall of the second part of the semiconductor layer.

10. The nonvolatile semiconductor memory device according to claim 4, wherein
the first wiring contains polysilicon, the second wiring containing metal.

11. The nonvolatile semiconductor memory device according to claim 10, wherein
a connection between the first wiring and the second wiring is an ohmic contact.

12. The nonvolatile semiconductor memory device according to claim 1, wherein
the variable resistance film is a transition metal oxide at least one kind selected from the group consisting of hafnium (Hf), chrome (Cr), tungsten (W), vanadium (V), niobium (Nb), tantalum (Ta), titanium (Ti), zirconium (Zr), scandium (Sc), yttrium (Y), thorium (Tr), manganese (Mn), iron (Fe), ruthenium (Ru), osmium (Os), cobalt (Co), nickel (Ni), copper (Cu), zinc (Zn), cadmium (Cd), aluminum (Al), gallium (Ga), indium (In), tin (Sn), lead (Pb), bismuth (Bi).

13. The nonvolatile semiconductor memory device according to claim 1, wherein
the first thickness and the second thickness have an average value of a thickness of the first part or the second part.

14. The nonvolatile semiconductor memory device according to claim 1, wherein
the variable resistance film has different film thicknesses in multiple levels in the first direction.

15. A nonvolatile semiconductor memory device, comprising
a memory cell array that includes a plurality of memory cells, wherein
the memory cell array includes:
a plurality of conducting layers laminated at predetermined pitches in a first direction perpendicular to a substrate, the plurality of conducting layers extending in a second direction parallel to the substrate;
variable resistance films disposed at side surfaces, top surfaces, and bottom surfaces of the plurality of conducting layers;
a semiconductor layer in contact with the side surfaces of the plurality of conducting layers via the variable resistance film, the semiconductor layer extending in the first direction; and
a first wiring opposed to the semiconductor layer via a gate insulating film, the first wiring extending in the first direction,
the variable resistance film has a first thickness at a first part, the first thickness being in a direction from the plurality of conducting layers to the semiconductor layer, and
the variable resistance film has a second thickness at a second part, the second part being further from the substrate than the first part, the second thickness being smaller than the first thickness, the second thickness being in a direction from the plurality of conducting layers to the semiconductor layer.

16. The nonvolatile semiconductor memory device according to claim 15, wherein
the semiconductor layer has a columnar shape that surrounds a peripheral area of the first wiring.

17. The nonvolatile semiconductor memory device according to claim 15, wherein
the first wiring, the gate insulating film, and the semiconductor layer constitute a transistor, the first wiring serving as a gate, the semiconductor layer serving as a channel.

18. The nonvolatile semiconductor memory device according to claim 15, wherein
the memory cell array has a second wiring extending in the second direction, the second wiring being electrically connected to an upper portion of the first wiring.

19. The nonvolatile semiconductor memory device according to claim 18, wherein
the plurality of first wirings are disposed along the second direction, and
the second wiring is electrically connected to the plurality of first wirings in common, the first wirings being disposed along the second direction.

20. The nonvolatile semiconductor memory device according to claim 15, further comprising
a third wiring electrically connected to a lower end of the semiconductor layer, the third wiring extending in a third direction.
